(19) United States
(12) Patent Application Publication
(10) Pub. No.: US 2025/0357363 A1
(43) Pub. Date: Nov. 20, 2025

(54) SEMICONDUCTOR DEVICE AND ELECTRIC POWER CONVERSION DEVICE

(71) Applicant: Mitsubishi Electric Corporation, Tokyo (JP)

(72) Inventors: Kazuya KONISHI, Tokyo (JP); Kohei ONDA, Tokyo (JP); Kohei SAKO, Tokyo (JP); Kakeru OTSUKA, Tokyo (JP); Masanori TSUKUDA, Tokyo (JP); Koyo MATSUZAKI, Tokyo (JP); Kosuke SAKAGUCHI, Tokyo (JP); Ryosuke KOBAYASHI, Tokyo (JP)

(73) Assignee: Mitsubishi Electric Corporation, Tokyo (JP)

(21) Appl. No.: 19/210,032

(22) Filed: May 16, 2025

(30) Foreign Application Priority Data
May 16, 2024 (JP) 2024-080264
Apr. 2, 2025 (JP) 2025-061318

(51) Int. Cl. H01L 23/552; H02M 1/44; H03K 17/04; H03K 17/16; H10D 12/00; H10D 62/10; H10D 62/60; H10D 64/27; H10D 84/00; H10D 84/80

(52) U.S. Cl. CPC H01L 23/552; H02M 1/44; H03K 17/0406; H03K 17/168; H10D 12/481; H10D 62/102; H10D 62/103; H10D 62/124; H10D 62/60; H10D 64/514; H10D 64/518; H10D 84/161; H10D 84/811; H10D 84/817

(57) ABSTRACT

An upper electrode is separated from a lower electrode inside a trench by an intermediate insulating film. A first resistor is connected between the upper electrode and the input terminal. A second resistor is connected between the lower electrode and the input terminal. Gate-emitter capacitance of the lower electrode is smaller than gate-emitter capacitance of the upper electrode.

### BACKGROUND OF THE INVENTION

### Field

The present disclosure relates to a semiconductor device and an electric power conversion device.

### Background

To reduce switching loss of an insulated gate bipolar transistor (IGBT), it is effective to increase switching speed. A problem of increasing the speed is that electromagnetic noise occurs. It has been reported that noise correlates with an IC peak at a low current (see, for example, Non Patent Literature 1). The IC peak depends on overshoot of a gate voltage Vge upon turn-on, and Vge increases as a displacement current (Idis=Cgc×dV/dt) is higher and Cge is smaller. Here, Cgc is gate-collector capacitance, and Cge is gate-emitter capacitance. It is therefore necessary to decrease a Cgc/Cge ratio to reduce electromagnetic noise.

Non Patent Literature 1: K. Nishi, T. Takahashi, and A. Narazaki, “Analysis the complex tradeoff among Eon-VCEsat-SCSOA and EMI noise through the single chip evaluation method,” in Proc. 31st Int. Symp. Power Semiconductor Devices ICs (ISPSD), May 2019, pp. 475-478

### SUMMARY

### Technical Problem

However, a structure of an IGBT capable of sufficiently reducing electromagnetic noise has not been proposed.

The present disclosure has been made to solve the problem as described above, and an object thereof is to provide a semiconductor device and an electric power conversion device capable of sufficiently reducing electromagnetic noise.

### Solution to Problem

A semiconductor device according to the present disclosure includes: a semiconductor substrate including a drift layer of a first conductive type, a base layer of a second conductive type formed on the drift layer, a source layer of a first conductive type formed on the base layer, and a collector layer of a second conductive type formed below the drift layer; an emitter electrode formed on an upper surface of the semiconductor substrate and connected to the base layer and the source layer; a collector electrode formed on a lower surface of the semiconductor substrate and connected to the collector layer; a lower electrode formed inside a trench penetrating the source layer and the base layer from the upper surface of the semiconductor substrate via a lower gate insulating film; an upper electrode formed inside the trench via an upper gate insulating film, positioned above the lower electrode and separated from the lower electrode by an intermediate insulating film; an input terminal; a first resistor connected between the upper electrode and the input terminal; and a second resistor connected between the lower electrode and the input terminal, wherein gate-emitter capacitance of the lower electrode is smaller than gate-emitter capacitance of the upper electrode.

### Advantageous Effects of Invention

In the present disclosure, the upper electrode is separated from the lower electrode by the intermediate insulating film inside the trench. The first resistor is connected between the upper electrode and the input terminal. The second resistor is connected between the lower electrode and the input terminal. Gate-emitter capacitance of the lower electrode is smaller than gate-emitter capacitance of the upper electrode. This results in making it possible to sufficiently reduce electromagnetic noise in the structure of the IGBT.

### BRIEF DESCRIPTION OF DRAWINGS

FIG. 1 is a cross-sectional view illustrating a semiconductor device according to a first embodiment.

FIG. 2 is a view indicating temporal change of Vce, Ic and Vge upon turn-on of the semiconductor device according to the first embodiment.

FIG. 3 is a view indicating a relationship between Cge2/Cge1 and the Ic peak.

FIG. 4 is a cross-sectional view illustrating a relationship of thicknesses of the insulating films of the semiconductor device according to the first embodiment.

FIG. 5 is a view indicating a relationship between the thickness of the lower gate insulating film/a thickness of the upper gate insulating film and Cge of the lower electrode/Cge of the upper electrode.

FIG. 6 is a view indicating a relationship between the thickness of the lower gate insulating film/the thickness of the upper gate insulating film and the Ic peak.

FIG. 7 is a cross-sectional view illustrating a relationship between a length of the carrier accumulation layer and a length of the drift layer in the semiconductor device according to the first embodiment.

FIG. 8 is a cross-sectional view illustrating a relationship between the lengths of the lower electrode and the upper electrode and a depth of the base layer in the semiconductor device according to the first embodiment.

FIG. 9 is a cross-sectional view illustrating a semiconductor device according to a second embodiment.

FIG. 10 is a top view illustrating a semiconductor device according to a third embodiment.

FIG. 11 is a cross-sectional view illustrating a cross-section along I-II and a cross-section along III-IV in FIG. 10.

FIG. 12 is a top view illustrating a modification of the semiconductor device according to the third embodiment.

FIG. 13 is a cross-sectional view illustrating a cross-section along I-II and a cross-section along III-IV in FIG. 12.

FIG. 14 is a view illustrating a semiconductor device according to a fourth embodiment.

FIG. 15 is a cross-sectional view illustrating a semiconductor device according to a fifth embodiment.

FIG. 16 is a cross-sectional view illustrating a semiconductor device according to a sixth embodiment.

FIG. 17 is a cross-sectional view illustrating a semiconductor device according to a seventh embodiment.

FIG. 18 is a cross-sectional view illustrating a modification of the semiconductor device according to the seventh embodiment.

FIG. 19 is a cross-sectional view illustrating a semiconductor device according to an eighth embodiment.

FIG. 20 is a top view illustrating a semiconductor device according to an eighth embodiment.

FIG. 21 is a cross-sectional view illustrating a semiconductor device according to a nineth embodiment.

FIG. 22 is a cross-sectional view illustrating a modification of the semiconductor device according to the nineth embodiment.

FIG. 23 is a cross-sectional view illustrating a semiconductor device according to a tenth embodiment.

FIG. 24 is a cross-sectional view illustrating a modification of the semiconductor device according to the tenth embodiment.

FIG. 25 is a cross-sectional view illustrating a semiconductor device according to an eleventh embodiment.

FIG. 26 is a cross-sectional view illustrating a modification of the semiconductor device according to the eleventh embodiment.

FIG. 27 is a cross-sectional view illustrating a semiconductor device according to a twelfth embodiment.

FIG. 28 is a cross-sectional view illustrating a modification of the semiconductor device according to the twelfth embodiment.

FIG. 29 is a cross-sectional view illustrating a semiconductor device according to a thirteenth embodiment.

FIG. 30 is a top view illustrating a semiconductor device according to a fourteenth embodiment.

FIG. 31 is a cross-sectional view illustrating a cross-section along I-II and a cross-section along III-IV in FIG. 30.

FIG. 32 is a top view illustrating a semiconductor device according to a fifteenth embodiment.

FIG. 33 is a cross-sectional view illustrating a semiconductor device according to a sixteenth embodiment.

FIG. 34 is a cross-sectional view illustrating a modification of the semiconductor device according to the sixteenth embodiment.

FIG. 35 is a view indicating Vce dependence of Cge.

FIG. 36 is a view indicating a relationship between the IC peak and the ratio of a CR time constant that is a product of gate-emitter capacitance of the upper electrode and the second resistance with respect to a CR time constant that is a product of gate-emitter capacitance of the upper electrode and the first resistance.

FIG. 37 is a view indicating a relationship between the IC peak and the ratio of the resistance of the second resistor with respect to the resistance of the first resistor.

FIG. 38 is a view indicating current and voltage of the lower and upper electrodes upon turn-on.

FIG. 39 is a block diagram illustrating a configuration of an electric power conversion system to which the electric power conversion device according to the seventeenth embodiment is applied.

### DESCRIPTION OF EMBODIMENTS

A semiconductor device and an electric power conversion device according to the embodiments of the present disclosure will be described with reference to the drawings. The same components will be denoted by the same symbols, and the repeated description thereof may be omitted.

### First Embodiment

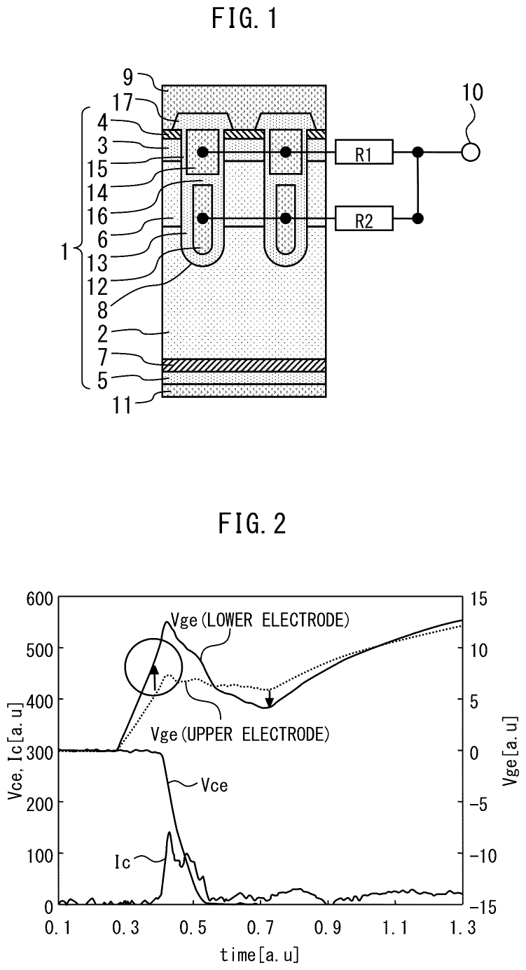

FIG. 1 is a cross-sectional view illustrating a semiconductor device according to a first embodiment. A semiconductor substrate 1 includes at least a first conductive type drift layer 2, a second conductive type base layer 3 formed on the drift layer 2, a first conductive type source layer 4 formed on part of the base layer 3, and a second conductive type collector layer 5 formed below the drift layer 2. A first conductive type carrier accumulation layer 6 is formed between the drift layer 2 and the base layer 3. A first conductive type buffer layer 7 is formed between the drift layer 2 and the collector layer 5. The carrier accumulation layer 6 and the buffer layer 7 have higher impurity concentration than that of the drift layer 2. For example, while the first conductive type is an n type, and the second conductive type is a p type, the conductive types may be inverse to each other. A plurality of trenches 8 that penetrate the source layer 4 and the base layer 3 from an upper surface of the semiconductor substrate 1 are formed side-by-side.

An emitter electrode 9 is formed on the upper surface of the semiconductor substrate 1 and is connected to the base layer 3 and the source layer 4. A gate electrode 10 is also formed on the upper surface of the semiconductor substrate 1. A collector electrode 11 is formed on a lower surface of the semiconductor substrate 1 and is connected to the collector layer 5. A lower electrode 12 is formed inside each of the trenches 8 via a lower gate insulating film 13. An upper electrode 14 is formed inside each of the trenches 8 via an upper gate insulating film 15, positioned above the lower electrode 12 and separated from the lower electrode 12 by an intermediate insulating film 16. An interlayer dielectric 17 is formed on the upper electrode 14 and separates the upper electrode 14 from the emitter electrode 9.

The intermediate insulating film 16 separates the upper electrode 14 from the lower electrode 12 inside the trench 8 as described above, and thus, gate-emitter capacitance Cge of the both electrodes can be made different from each other. While the upper electrode 14 faces the base layer 3 connected to the emitter electrode 9, and thus, Cge becomes great, the lower electrode 12 does not face the base layer 3, and thus, Cge becomes small.

Further, a first resistor R1 is connected between the upper electrode 14 and the gate electrode 10, and a second resistor R2 is connected between the lower electrode 12 and the gate electrode 10. This enables voltages of the upper electrode 14 and the lower electrode 12 to be individually controlled by the respective gate capacitance. Thus, a thickness of a gate oxide film of each electrode, and the like, are adjusted so that Cge of the lower electrode 12 becomes smaller than Cge of the upper electrode 14. This increases charging speed of capacitance of the lower electrode 12.

FIG. 2 is a view indicating temporal change of Vce, Ic and Vge upon turn-on of the semiconductor device according to the first embodiment. The charging speed of the capacitance of the lower electrode 12 is higher as described above, and thus, there is a period during which a voltage of the lower electrode 12 is higher than a voltage of the upper electrode 14 during a current increase period upon turn-on. There is a period during which the voltage of the lower electrode 12 is lower than the voltage of the upper electrode 14 during a miller period after the current increase period.

If the voltage of the lower electrode 12 becomes higher, a potential of a mesa portion placed between the lower electrodes 12 of the adjacent trenches 8 in a lateral direction also increases. Cgc is a serial connection of capacitance of the gate oxide film and capacitance of a depletion layer, and if the potential increases and the depletion layer extends, Cgc is decreased. Thus, a displacement current to the upper electrode 14 can be reduced, which makes the Ic peak smaller. This results in making it possible to sufficiently reduce electromagnetic noise in the structure of the IGBT.

Note that the electromagnetic noise is caused by increase of the IC peak as a result of the displacement current becoming greater due to a hole and is a problem that occurs in the IGBT in which a large amount of holes flows. On the other hand, in an MOSFET, increase of the Ic peak does not prominently occur, and thus, even if the structure of the present embodiment is applied to the MOSFET, the IC peak cannot be sufficiently made smaller.

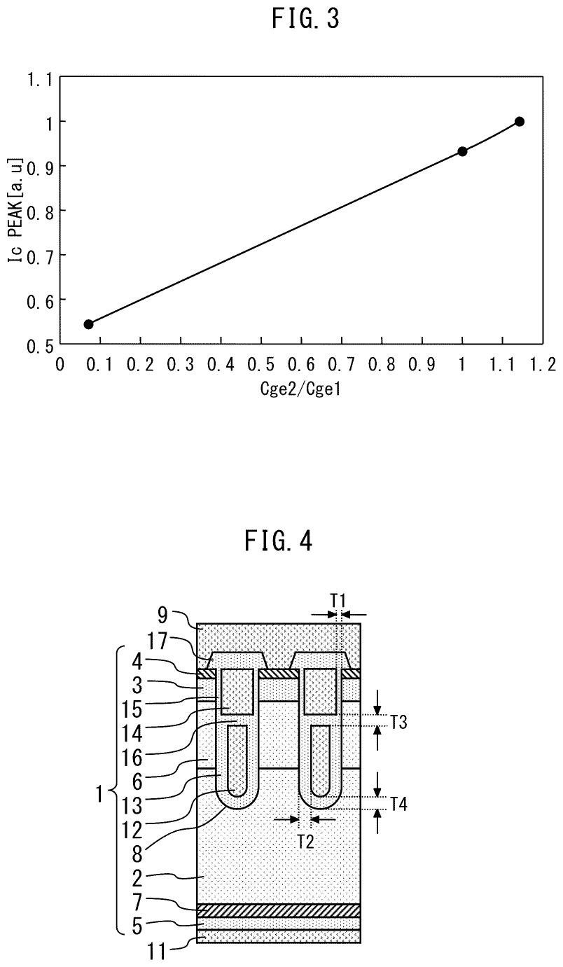

FIG. 3 is a view indicating a relationship between Cge2/Cge1 and the Ic peak. FIG. 3 indicates a ratio of gate-emitter capacitance Cge2 of the electrode connected to the second resistor R2 with respect to gate-emitter capacitance Cge1 of the electrode connected to the first resistor R1 (Cge2/Cge1) on a horizontal axis. The inventor has newly found that the IC peak can be made smaller by making Cge2/Cge1 smaller. By making Cge2/Cge1 equal to or less than 0.5, the IC peak can be made smaller by equal to or greater than 30%, and by making Cge2/Cge1 equal to or less than 0.2, the IC peak can be made smaller by equal to or greater than 40%. Thus, in the present embodiment, the ratio of Cge of the electrode connected to the lower electrode 12 with respect to Cge of the upper electrode 14 is preferably made equal to or less than 0.5 and further preferably made equal to or less than 0.2.

Further, there is a period during which the voltage of the lower electrode 12 is lower than the voltage of the upper electrode 14 during the miller period after the current increase period upon turn-on. The miller period does not affect the Ic peak, and thus, even if the voltage of the lower electrode 12 is low, the IC peak does not increase. By making the voltage of the lower electrode 12 smaller during the miller period, a voltage to be applied to the gate oxide film can be decreased. It is therefore possible to extend the life of the gate oxide film compared to a case where the voltage of the lower electrode 12 is always high. On the other hand, if there is a period during which the voltage of the lower electrode 12 is higher than the voltage of the upper electrode 14 during the miller period, Cgc can be decreased.

FIG. 4 is a cross-sectional view illustrating a relationship of thicknesses of the insulating films of the semiconductor device according to the first embodiment. A thickness T2 of the lower gate insulating film 13 that covers a side surface of the lower electrode 12 and a thickness T4 of the lower gate insulating film 13 that covers a bottom portion of the lower electrode 12 are thicker than a thickness T1 of the upper gate insulating film 15 that covers a side surface of the upper electrode 14. By this means, Cge of the lower electrode 12 becomes smaller than Cge of the upper electrode 14, and thus, the charging speed of the capacitance of the lower electrode 12 becomes higher as described above, so that it is possible to make the voltage of the lower electrode 12 higher and make Cgc smaller, thereby reducing electromagnetic noise.

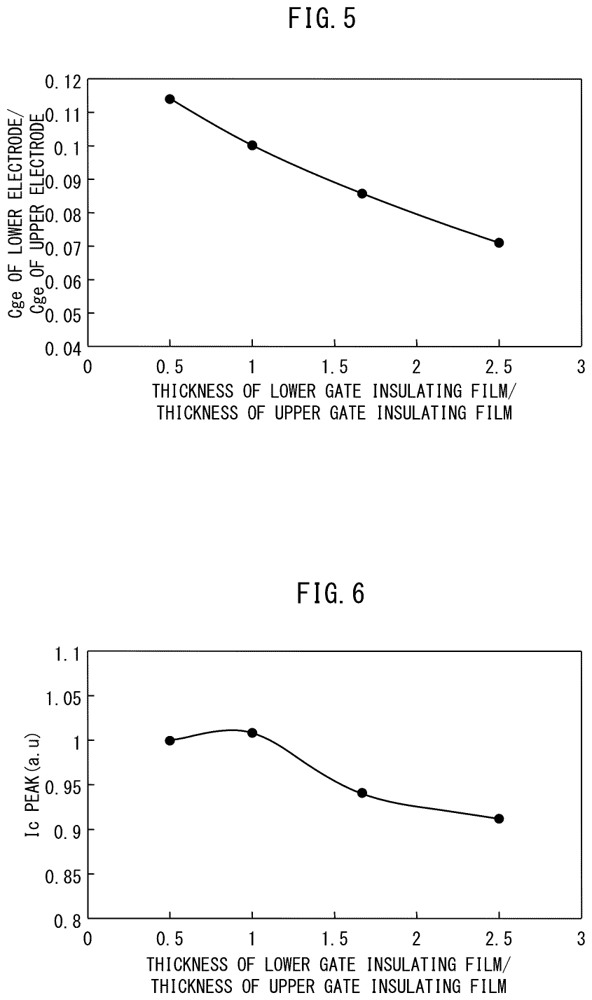

FIG. 5 is a view indicating a relationship between the thickness of the lower gate insulating film/a thickness of the upper gate insulating film and Cge of the lower electrode/Cge of the upper electrode. FIG. 6 is a view indicating a relationship between the thickness of the lower gate insulating film/the thickness of the upper gate insulating film and the Ic peak. To decrease the ratio of Cge of the lower electrode/Cge of the upper electrode to decrease the Ic peak, the thickness of the lower gate insulating film 13 is preferably made equal to or greater than 1.5 times of the thickness of the upper gate insulating film 15, further preferably made equal to or greater than double, and still further preferably made equal to or greater than 2.5 times.

Further, when the potential of the lower electrode 12 becomes high, a potential difference occurs between the upper electrode 14 and the lower electrode 12, and capacitance occurs. Thus, a thickness T3 of the intermediate insulating film 16 is made thicker than the thickness T1 of the upper gate insulating film 15 on the side surface of the upper electrode 14. This decreases Cge of the lower electrode 12, and thus, the charging speed of the capacitance of the lower electrode 12 becomes higher as described above, which makes it possible to make the voltage of the lower electrode 12 higher and make Cgc smaller, thereby reducing electromagnetic noise. Further, a CR time constant comprised of gate capacitance (Cies2=Cge+Cgc) of the lower electrode 12 and the second resistor R2 is smaller than a CR time constant comprised of gate capacitance (Cies1=Cge+Cgc) of the upper electrode 14 and the first resistor R1. This increases the charging speed of the capacitance of the lower electrode 12, so that electromagnetic noise can be reduced.

Further, a resistance value of the second resistor R2 is smaller than a resistance value of the first resistor R1. This increases the charging speed of the capacitance of the lower electrode 12, so that electromagnetic noise can be reduced. On the other hand, if the resistance value of the second resistor R2 is greater than the resistance value of the first resistor R1, rising of the gate voltage determined by the displacement current and electric resistance increases. Thus, the voltage of the lower electrode 12 can be made higher than the voltage of the upper electrode 14, so that Cgc can be decreased.

Further, impurity concentration of the carrier accumulation layer 6 is higher than impurity concentration of the drift layer 2, and thus, the voltage of the lower electrode 12 is easily increased. It is therefore possible to further decrease Cgc and reduce electromagnetic noise by forming the carrier accumulation layer 6.

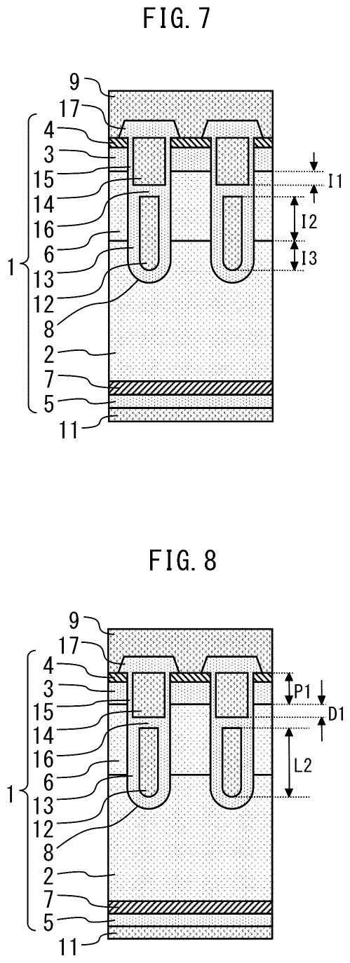

FIG. 7 is a cross-sectional view illustrating a relationship between a length of the carrier accumulation layer and a length of the drift layer in the semiconductor device according to the first embodiment. A length 12 of the carrier accumulation layer 6 facing the lower electrode 12 is longer than a length I1 of the carrier accumulation layer 6 facing the upper electrode 14. By increasing a region where the lower electrode 12 faces the carrier accumulation layer 6, it is possible to increase the voltage of the lower electrode 12 and decrease Cgc. By reducing a region where the upper electrode 14 faces the carrier accumulation layer 6, it is possible to decrease Cgc of the upper electrode.

Further, the length 12 of the carrier accumulation layer 6 facing the side surface of the lower electrode 12 is longer than a length 13 of the drift layer 2 facing the side surface of the lower electrode 12. Impurity concentration of the carrier accumulation layer 6 is higher than impurity concentration of the drift layer 2, and thus, the voltage of the lower electrode 12 is easily increased. Thus, by increasing a region where the lower electrode 12 faces the carrier accumulation layer 6, it is possible to increase the voltage of the lower electrode 12 and decrease Cgc.

FIG. 8 is a cross-sectional view illustrating a relationship between the lengths of the lower electrode and the upper electrode and a depth of the base layer in the semiconductor device according to the first embodiment. Cgc depends on an area of the electrode facing the drift layer 2 and the carrier accumulation layer 6, and thus, a length D1 of the upper electrode 14 extending below the base layer 3 is proportional to Cgc of the upper electrode 14, and a length L2 of the lower electrode 12 is proportional to Cgc of the lower electrode 12. In the present embodiment, the length L2 is longer than the length D1. A depth P1 of the base layer 3 is longer than the length D1.

In a region below the base layer 3 where the voltage changes, by shortening an overhang length D1 of the upper electrode 14 at a low voltage, the depletion layer can be extended, so that Cgc of the upper electrode 14 can be decreased, and a peak current Ic can be reduced. To sufficiently decrease Cgc of the upper electrode 14, the overhang length D1 of the upper electrode 14 is preferably made equal to or less than half the length L2 of the lower electrode 12, and further preferably made equal to or less than ⅓.

### Second Embodiment

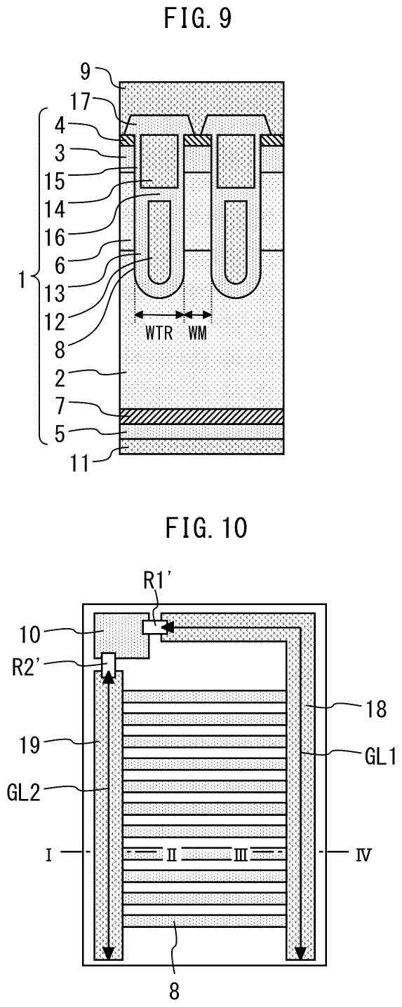

FIG. 9 is a cross-sectional view illustrating a semiconductor device according to a second embodiment. A plurality of trenches 8 are formed on the semiconductor substrate 1 side-by-side. A mesa width WM between the adjacent trenches 8 is narrower than a width WTR of the trench 8. This can increase the voltage of the mesa portion and decrease Cgc, so that it is possible to reduce electromagnetic noise. Other configurations and effects are similar to those of the first embodiment.

### Third Embodiment

FIG. 10 is a top view illustrating a semiconductor device according to a third embodiment. A first gate wiring 18 and a resistor R1′ connect the upper electrode 14 and the gate electrode 10. A second gate wiring 19 and a resistor R2′ connect the lower electrode 12 and the gate electrode 10. The first resistor R1 is a sum of resistance of the resistor R1′ and the first gate wiring 18. The second resistor R2 is a sum of resistance of the resistor R2′ and the second gate wiring 19. A length GL2 of the second gate wiring 19 is shorter than a length GL1 of the first gate wiring 18. Thus, even if a resistance value of the resistor R1′ is the same as a resistance value of the resistor R2′, the resistance value of the second resistor R2 is smaller than the resistance value of the first resistor R1. This increases the charging speed of the capacitance of the lower electrode 12, so that it is possible to reduce electromagnetic noise.

On the other hand, if the length GL2 of the second gate wiring 19 is longer than the length GL1 of the first gate wiring 18, the resistance value of the second resistor R2 becomes greater. Thus, rising of the gate voltage determined by the displacement current and electric resistance increases, so that the voltage of the lower electrode 12 can be made higher than the voltage of the upper electrode 14, and Cgc can be decreased.

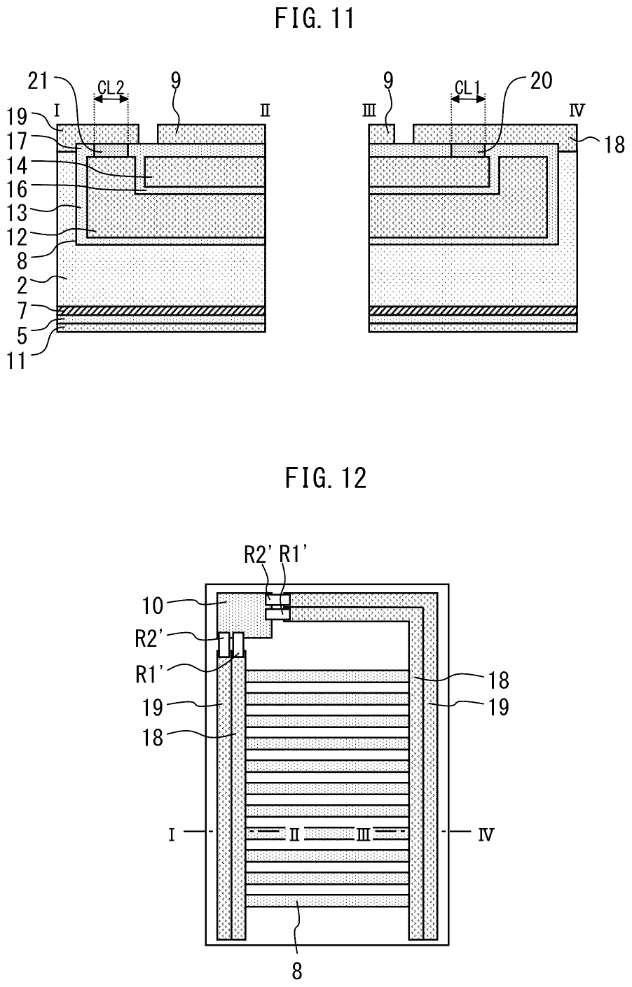

FIG. 11 is a cross-sectional view illustrating a cross-section along I-II and a cross-section along III-IV in FIG. 10. The upper electrode 14 is connected to the first gate wiring 18 via a first gate contact 20. The lower electrode 12 is connected to the second gate wiring 19 via a second gate contact 21. Other configurations and effects are similar to those of the first embodiment.

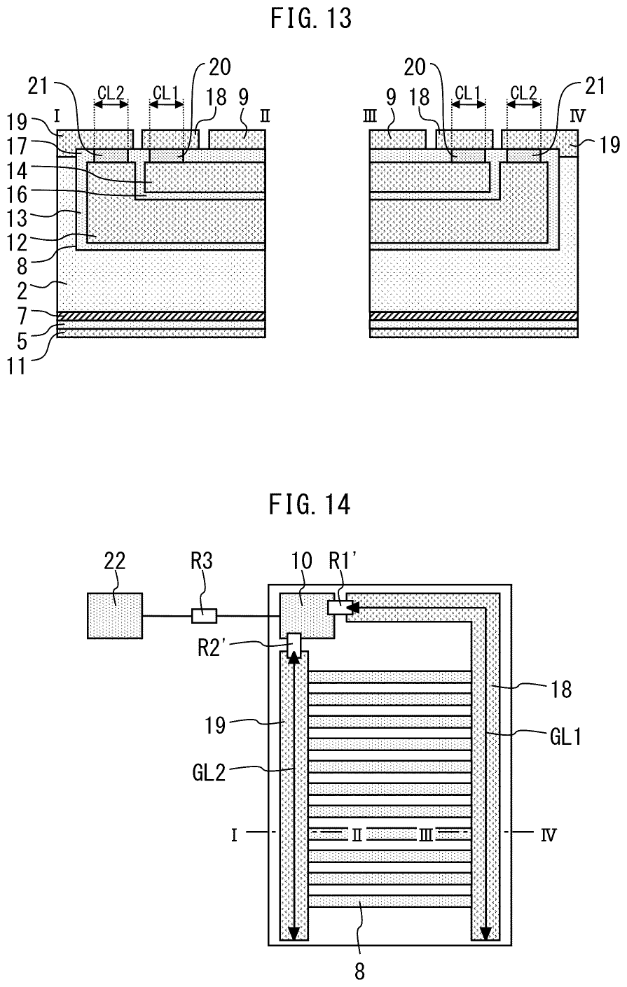

FIG. 12 is a top view illustrating a modification of the semiconductor device according to the third embodiment. FIG. 13 is a cross-sectional view illustrating a cross-section along I-II and a cross-section along III-IV in FIG. 12. The upper electrode 14 is connected to the first gate wiring 18 via a plurality of first gate contacts 20. The lower electrode 12 is connected to the second gate wiring 19 via a plurality of second gate contacts 21. Further, by forming the first gate wiring 18 and the second gate wiring 19 doubly in a peripheral portion of the substrate and inside thereof, it is possible to increase contact portions with the upper electrode 14 or the lower electrode 12. This enables gate operation without a gate delay in a chip plane.

### Fourth Embodiment

FIG. 14 is a view illustrating a semiconductor device according to a fourth embodiment. A gate drive circuit 22 supplies a gate signal to the gate electrode 10. A gate resistor R3 is connected between the gate drive circuit 22 and the gate electrode 10 to adjust the switching speed. The gate resistor R3 has a resistance value greater than the resistance values of the first resistor R1 and the second resistor R2. If large electric resistance is formed inside the chip, an energized region is reduced, conduction loss increases, and an element size and manufacturing cost also increase. To avoid this, the gate resistor R3 is formed outside the semiconductor substrate 1. This can reduce a resistance region within the substrate, so that it is possible to reduce conduction loss, an element size and manufacturing cost. Other configurations and effects are similar to those of the first embodiment.

Further, the gate resistor R3 may have a smaller resistance value than the first resistor R1 and the second resistor R2. This enables the currents flowing through the first resistor R1 and the second resistor R2 to increase, compared to when the gate resistor R3 has a greater resistance value. Therefore, since the voltage amount of the upper 14 and lower 12 electrodes individually controlled by the respective gate capacitances, the first resistor R1 and the second resistor R2 can be increased, it becomes easier to control to the optimal voltage value, and furthermore, electromagnetic noise can be reduced. By adjusting the gate current with the gate resistor R3 connected between the gate drive circuit 22 and the semiconductor device, it is possible to fine-tune the switching speed according to the application of the device or peripheral equipment. This allows for reducing electromagnetic noise that adversely affects peripheral components while also decreasing switching loss.

### Fifth Embodiment

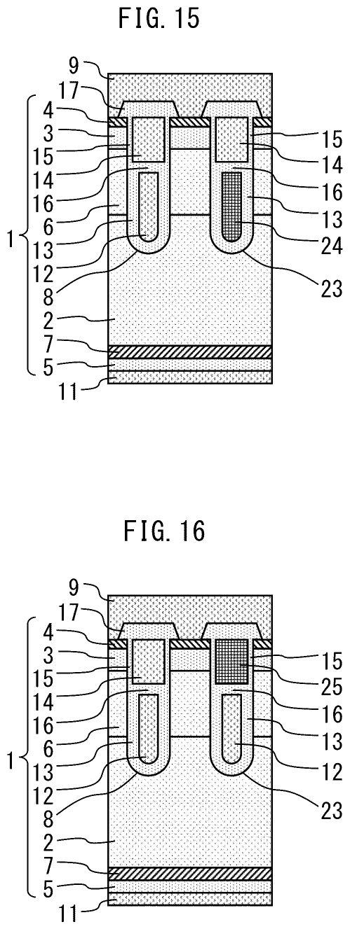

FIG. 15 is a cross-sectional view illustrating a semiconductor device according to a fifth embodiment. A plurality of trenches 8 and a plurality of dummy trenches 23 are formed on the semiconductor substrate 1 side-by-side. The dummy trenches 23 penetrate the source layer 4 and the base layer 3 from the upper surface of the semiconductor substrate 1 in a similar manner to the trenches 8. The dummy trenches 23 have the same depth and width as those of the trenches 8.

A dummy lower electrode 24 is formed inside each of the dummy trenches 23 via the lower gate insulating film 13. The dummy lower electrode 24 is connected to the emitter electrode 9. A material, a length, a width, and the like, of the dummy lower electrode 24 are the same as those of the lower electrode 12. The upper electrode 14 is formed inside each of the dummy trenches 23 via the upper gate insulating film 15, positioned above the dummy lower electrode 24, and separated from the dummy lower electrode 24 by the intermediate insulating film 16.

By forming the dummy lower electrode 24, a ratio of the lower electrode 12 connected to the gate electrode 10 is reduced, and a ratio of the dummy lower electrode 24 connected to the emitter electrode 9 increases in the whole of the plurality of trenches including the trenches 8 and the dummy trenches 23. It is therefore possible to reduce gate capacitance parasitic in the lower electrode 12. This can increase the charging speed of the capacitance of the lower electrode 12, increase the voltage of the lower electrode 12, and decrease Cgc. Other configurations and effects are similar to those of the first embodiment.

### Sixth Embodiment

FIG. 16 is a cross-sectional view illustrating a semiconductor device according to a sixth embodiment. The dummy upper electrode 25 is formed inside each of the dummy trenches 23 via the upper gate insulating film 15. A material, a length, a width, and the like, of the dummy upper electrode 25 are the same as those of the upper electrode 14. The lower electrode 12 is formed inside each of the dummy trenches 23 via the lower gate insulating film 13, positioned below the dummy upper electrode 25, and separated from the dummy upper electrode 25 via the intermediate insulating film 16. By forming the dummy upper electrode 25, Cge that becomes coupling capacitance between the upper electrode 14 and the dummy upper electrode 25 occurs. Increase of the gate voltage of the upper electrode 14 can be reduced by this coupling capacitance, so that it is possible to reduce electromagnetic noise. Other configurations and effects are similar to those of the fifth embodiment.

### Seventh Embodiment

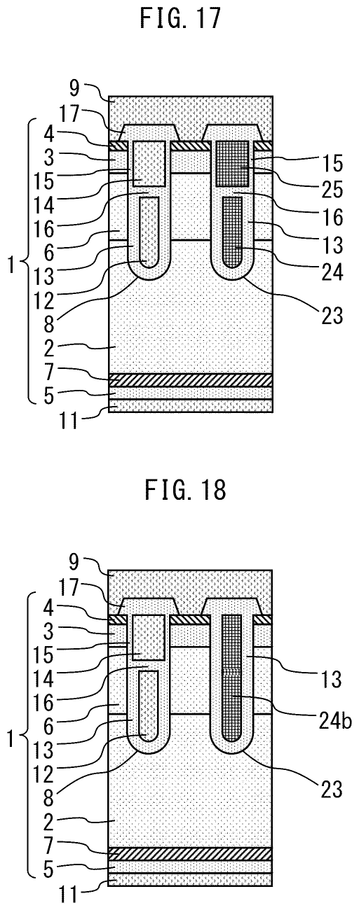

FIG. 17 is a cross-sectional view illustrating a semiconductor device according to a seventh embodiment. The dummy lower electrode 24 in the fifth embodiment and the dummy upper electrode 25 in the sixth embodiment are formed in each of the dummy trenches 23. In the fifth embodiment, Cge is parasitic between the upper electrode 14 and the dummy lower electrode 24. On the other hand, in the present embodiment, Cge can be decreased by providing dummy electrodes as both the upper and lower electrodes, so that it is possible to reduce gate capacitance parasitic in the lower electrode 12 compared to the fifth embodiment. It is therefore possible to increase the charging speed of the capacitance of the lower electrode 12, increase the voltage of the lower electrode 12 and decrease Cgc. Other configurations and effects are similar to those of the fifth embodiment.

Further, the electric field is concentrated at the corner section of the bottom surface of the dummy upper electrode 25 due to its shape, which may result in a decrease in breakdown voltage. FIG. 18 is a cross-sectional view illustrating a modification of the semiconductor device according to the seventh embodiment. A dummy electrode 24b is formed inside the dummy trench 23 via a lower gate insulating film 13. The dummy electrode 24b is connected to the emitter electrode 9. By not dividing the dummy electrode 24b vertically, corners are eliminated at the bottom surface of the dummy upper electrode 25, thus improving the breakdown voltage. Note that the insulating film covering the dummy electrode 24b can be an upper gate insulating film 15. However, by adopting the lower gate insulating film 13 being thick, it is possible to prevent the breakdown of the insulating film.

### Eighth Embodiment

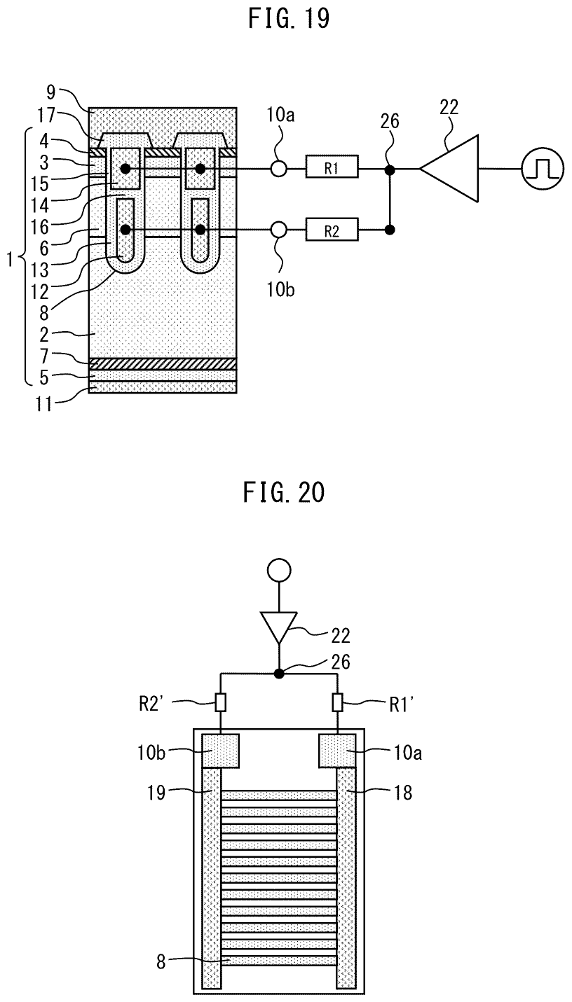

FIG. 19 is a cross-sectional view illustrating a semiconductor device according to an eighth embodiment. Instead of the gate electrode 10 of the first embodiment, the first gate electrode 10a and the second gate electrode 10b are separately formed on the upper surface of the semiconductor substrate 1. The first gate electrode 10a is connected to the upper electrode 14. The second gate electrode 10b is connected to the lower electrode 12. Outside the semiconductor substrate 1, the first resistor R1 is connected between the first gate electrode 10a and the input terminal 26, and the second resistor R2 is connected between the second gate electrode 10b and the input terminal 26. The gate drive circuit 22 supplies a gate signal to the input terminal 26 in response to the signal from the microcontroller.

Further, the semiconductor chip including the semiconductor substrate 1, the first resistor R1, the second resistor R2, and the gate drive circuit 22 are mounted and integrated on a circuit board. The first gate electrode 10a and the second gate electrode 10b are wire-connected to pads on the circuit board, respectively. These structures are connected by wiring on the circuit board.

In the present embodiment, the first resistor R1 is connected between the upper electrode 14 and the input terminal 26, and the second resistor R2 is connected between the lower electrode 12 and the input terminal 26. Also, similar to the first embodiment, Cge of the lower electrode 12 is smaller than Cge of the upper electrode 14. As a result, similar to the first embodiment, electromagnetic noise can be sufficiently suppressed in the structure of the IGBT.

Further, traditionally, two gate drive circuits were separately connected to the first gate electrode 10a and the second gate electrode 10b to individually control the voltages of the upper electrode 14 and the lower electrode 12. In contrast, in the present embodiment, because the voltages of the upper electrode 14 and the lower electrode 12 can be individually controlled by a single gate drive circuit 22, costs can be reduced.

Further, the input terminal 26, the first resistor R1, and the second resistor R2 are formed outside the semiconductor substrate 1. As a result, the resistance region in the substrate can be reduced, thereby allowing a reduction in conduction loss, device size, and manufacturing cost. Note that for the first resistor R1 and the second resistor R2, a combination of a resistor inside the substrate and a resistor outside the substrate connected in series can also be used. This allows the resistance region in the substrate to be reduced.

Further, it is preferable that the resistance value of the second resistor R2 is smaller than the resistance value of the first resistor R1. This allows the charging of the capacitance of the lower electrode 12 to become faster, thereby being able to suppress electromagnetic noise. On the other hand, if the resistance value of the second resistor R2 is larger than that of the first resistor R1, the rise in gate voltage determined by the displacement current and electrical resistance increases. For this reason, the voltage of the lower electrode 12 can be made higher than that of the upper electrode 14, thus reducing Cgc.

FIG. 20 is a top view illustrating a semiconductor device according to an eighth embodiment. The first gate wiring 18 and the resistor R1′ connect the upper electrode 14 and the input terminal 26. The second gate wiring 19 and the resistor R2′ connect the lower electrode 12 and the input terminal 26. The first resistor R1 is the sum of the resistor R1′ and the resistance of the first gate wiring 18. The second resistor R2 is the sum of the resistor R2′ and the resistance of the second gate wiring 19. Note that if the length GL2 of the second gate wiring 19 is shorter than the length GL1 of the first gate wiring 18, the resistance value of the second resistor R2 will be smaller than the resistance value of the first resistor R1, even if the resistance values of R1′ and R2′ are the same.

### Nineth Embodiment

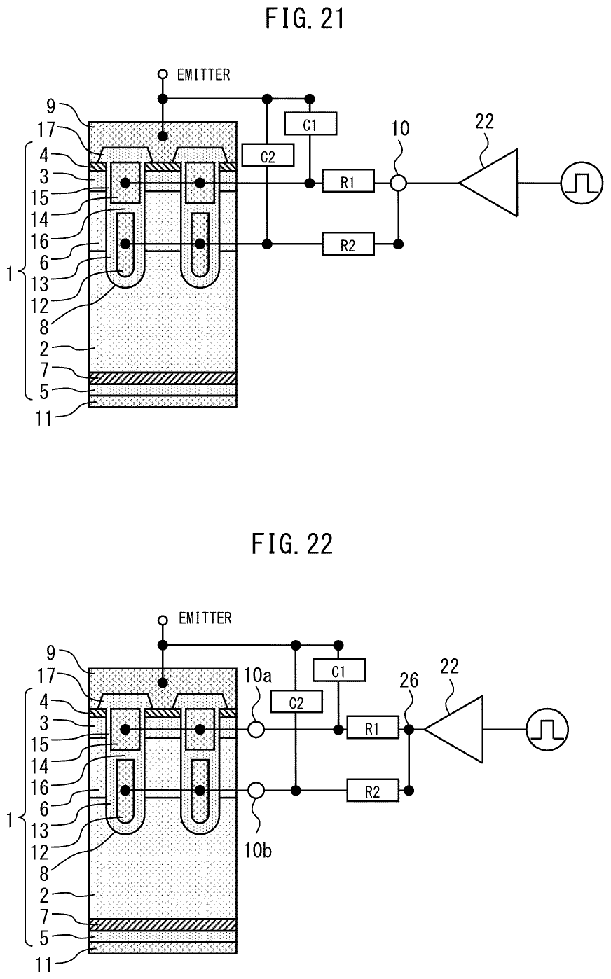

FIG. 21 is a cross-sectional view illustrating a semiconductor device according to a nineth embodiment. The first capacitor C1 is connected between the upper electrode 14 and the emitter. The second capacitor C2 is connected between the lower electrode 12 and the emitter. The first capacitance C1 and the second capacitor C2 are formed outside the semiconductor substrate 1. The second capacitor C2 is smaller than the first capacitor C1. Therefore, the sum of the Cge of the lower electrode 12 and the second capacitor C2 is smaller than the sum of the Cge of the upper electrode 14 and the first capacitance C1. Other configurations are the same as in the first embodiment. It is also possible to provide only one of the first capacitor C1 and the second capacitor C2.

By adding the first capacitor C1 and the second capacitor C2, in addition to the gate capacitance parasitic in the upper electrode 14 and the lower electrode 12, the voltages of the upper electrode 14 and the lower electrode 12 can be individually controlled by the additional first capacitor C1 and the second capacitor C2, as well as their gate capacitances. For this reason, the control range of the voltage is expanded, allowing further reduction of electromagnetic noise.

Further, the displacement current can be divided into components flowing into the parasitic gate capacitance of the upper electrode 14 and the lower electrode 12, and components flowing into the first capacitor C1 and the second capacitor C2, thus the displacement current flowing into the gate-emitter capacitance parasitic to the upper electrode 14 and the lower electrode 12 can be reduced. This allows the overshoot of the voltage of the upper electrode 14 to be reduced, which can decrease Icp, thereby reducing electromagnetic noise.

FIG. 22 is a cross-sectional view illustrating a modification of the semiconductor device according to the nineth embodiment. The first capacitor C1 is connected between the first gate electrode 10a and the emitter. The second capacitor C2 is connected between the second gate electrode 10b and the emitter. The first capacitor C1 and the second capacitor C2 are formed outside the semiconductor substrate 1. Other configurations are the same as in the eighth embodiment. Even in this case, the above effects can be obtained.

### Tenth Embodiment

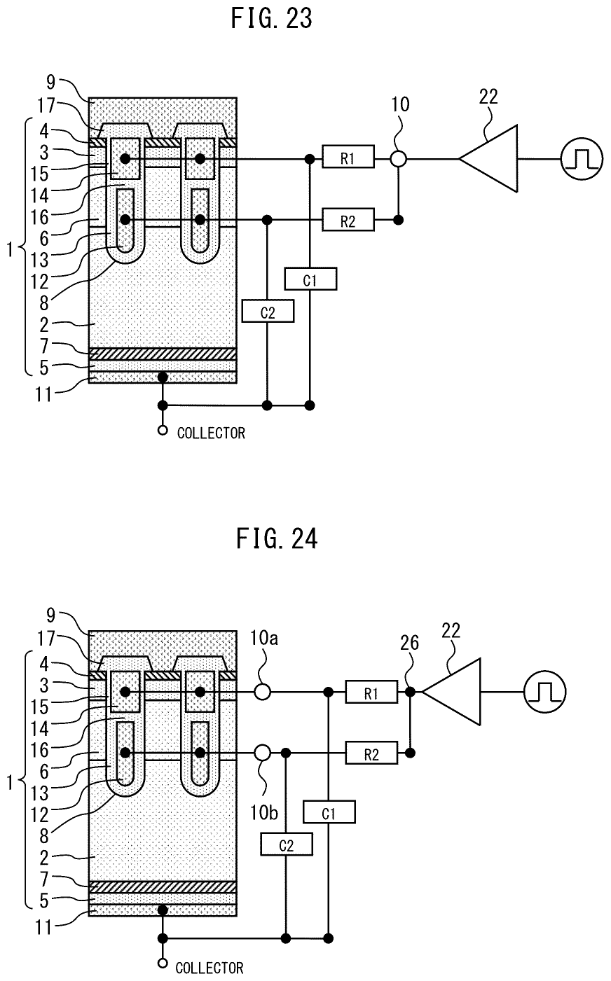

FIG. 23 is a cross-sectional view illustrating a semiconductor device according to a tenth embodiment. The first capacitance C1 is connected between the upper electrode 14 and the collector. The second capacitor C2 is connected between the lower electrode 12 and the collector. The first capacitor C1 and the second capacitor C2 are formed outside the semiconductor substrate 1. Other configurations are the same as in the first embodiment. It is acceptable to provide only one of the first capacitance C1 and the second capacitor C2.

By adding the first capacitor C1 and the second capacitor C2, in addition to the gate capacitance parasitic in the upper electrode 14 and the lower electrode 12, the voltages of the upper electrode 14 and the lower electrode 12 can be individually controlled by the additional first capacitor C1 and the second capacitor C2, as well as their gate capacitances. For this reason, the control range of the voltage is expanded, and electromagnetic noise can be further reduced. By particularly adding the capacitance between the gate and the collector, which has a correlation with dV/dt, the dV/dt can be smoothed, generation of displacement current can be suppressed, and electromagnetic noise can be reduced.

FIG. 24 is a cross-sectional view illustrating a modification of the semiconductor device according to the tenth embodiment. The first capacitance C1 is connected between the first gate electrode 10a and the collector. The second capacitor C2 is connected between the second gate electrode 10b and the collector. The first capacitance C1 and the second capacitor C2 are formed outside the semiconductor substrate 1. Other configurations are the same as in eighth embodiment. In this case as well, the aforementioned effects can be obtained.

### Eleventh Embodiment

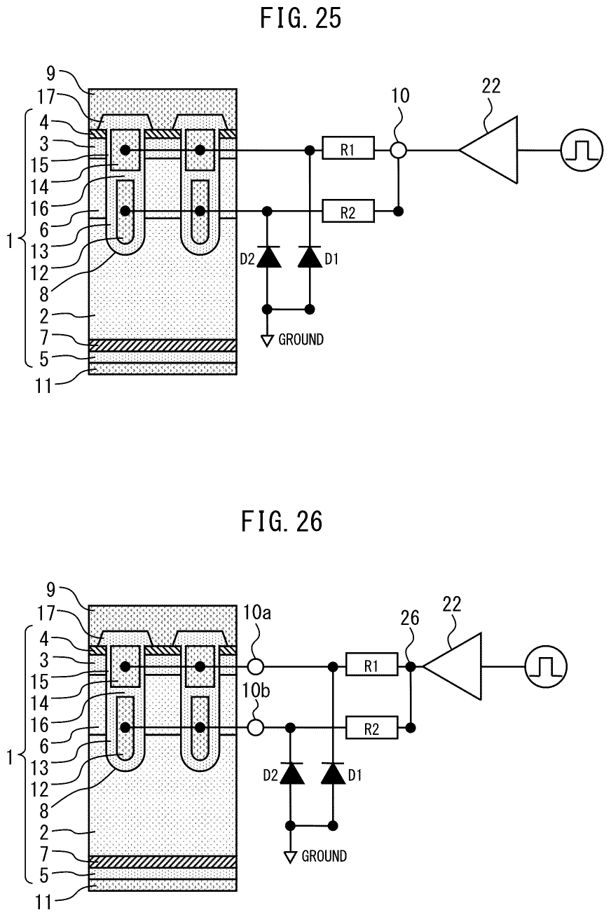

FIG. 25 is a cross-sectional view illustrating a semiconductor device according to an eleventh embodiment. The cathode of the first diode D1 is connected to the upper electrode 14, and the anode is connected to the ground or emitter. The cathode of the second diode D2 is connected to the lower electrode 12, and the anode is connected to the ground or emitter. The first diode D1 and the second diode D2 are formed outside the semiconductor substrate 1. Other configurations are similar to first embodiment. Note that it is acceptable to provide only one of the first diode D1 and the second diode D2.

By adding the first diode D1 and the second diode D2, it is possible to add junction capacitance parasitic on the diodes. As a result, the voltages of the upper electrode 14 and the lower electrode 12 can be controlled by the gate capacitance and the junction capacitance, which increases the control range of the voltage, further reduces the overshoot of Vge due to displacement current, and reduces electromagnetic noise more effectively.

FIG. 26 is a cross-sectional view illustrating a modification of the semiconductor device according to the eleventh embodiment. The cathode of the first diode D1 is connected to the first gate electrode 10a, and the anode is connected to the ground or the emitter. The cathode of the second diode D2 is connected to the second gate electrode 10b, and the anode is connected to the ground or the emitter. The first diode D1 and the second diode D2 are formed outside the semiconductor substrate 1. The other configurations are the same as the eighth embodiment. In this case as well, the above effects can be obtained.

### Twelfth Embodiment

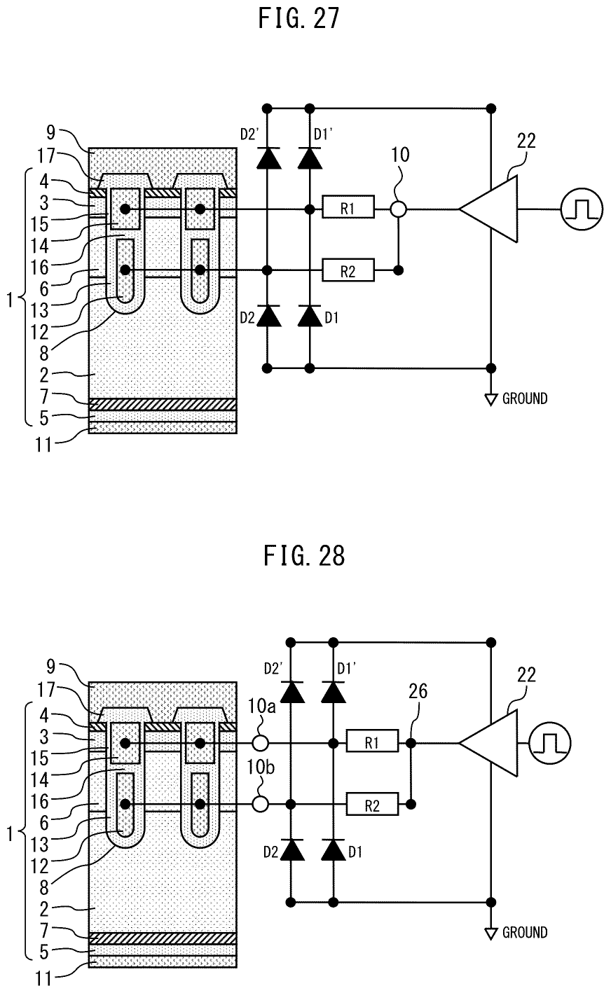

FIG. 27 is a cross-sectional view illustrating a semiconductor device according to a twelfth embodiment. In addition to the first diode D1 and the second diode D2 of the eleventh embodiment, a first diode D1′ and a second diode D2′ are provided. The cathode of the first diode D1 is connected to the power supply of the gate drive circuit 22, and the anode is connected to the upper electrode 14. The cathode of the second diode D2′ is connected to the power supply of the gate drive circuit 22, and the anode is connected to the lower electrode 12. The first diodes D1 and D1′ form a first clamp circuit connected to the upper electrode 14, and the second diodes D2 and D2′ form a second clamp circuit connected to the lower electrode 12. Other configurations are the same as those in the first embodiment. It is also possible to provide only one of the first and second clamp circuits.

In the present disclosure, the voltages of the upper electrode 14 and the lower electrode 12 are controlled separately, making it easy for the voltage to increase. By providing the above-mentioned clamp circuit, it is possible to limit the voltage even if an overvoltage is applied to the upper electrode 14 or the lower electrode 12. Therefore, it is possible to suppress abnormal operation and improve the breakdown endurance.

FIG. 28 is a cross-sectional view illustrating a modification of the semiconductor device according to the twelfth embodiment. The first clamp circuit is connected to the first gate electrode 10a, and the second clamp circuit is connected to the second gate electrode 10b. The other configurations are the same as the eighth embodiment. In this case as well, the above effects can be obtained.

### Thirteenth Embodiment

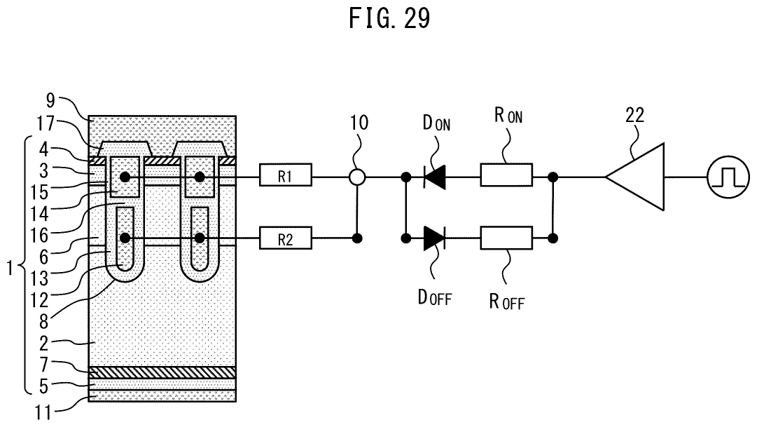

FIG. 29 is a cross-sectional view illustrating a semiconductor device according to a thirteenth embodiment. The on-side diode D_{ON}, the off-side diode D_{OFF}, the on-resistor R_{ON}, and the off-resistor R_{OFF} are provided outside the semiconductor substrate 1 and are connected to the gate electrode 10. The cathode of the on-side diode D_{ON} and the anode of the off-side diode D_{OFF} are connected to the input terminal 26. The off-side diode D_{OFF} is connected in reverse-parallel to the on-side diode D_{ON}. The on-resistor R_{ON} is connected in series to the on-side diode D_{ON}. The off-resistor R_{OFF} is connected in series to the off-side diode D_{OFF}. Other configurations are the same as in first embodiment.

Since the on and off signals of the gate signal flow through the first resistor R1 and the second resistor R2 in common, the turn-on and turn-off speeds cannot be optimally adjusted independently. Thus, the on-side diode D_{ON} and the off-side diode D_{OFF}, which are connected in reverse parallel, are each connected in series with an on-resistor R_{ON} and an off-resistor R_{OFF}, respectively. This allows the separation of the on and off signals. The resistance values of the on-resistance R_{ON} and off-resistance R_{OFF} allow for optimal control by changing the signals for turn-on and turn-off respectively.

### Fourteenth Embodiment

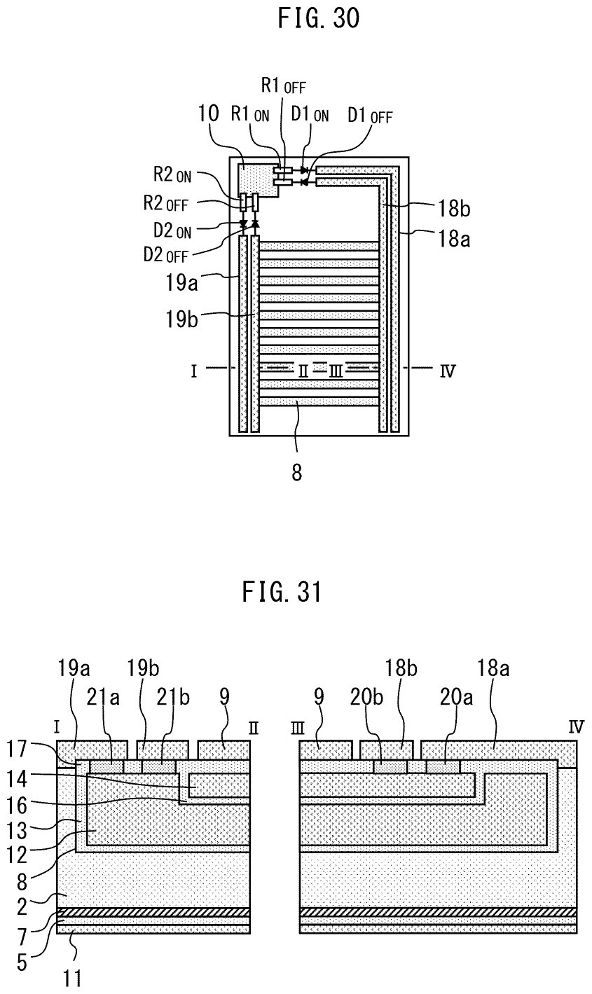

FIG. 30 is a top view illustrating a semiconductor device according to a fourteenth embodiment. FIG. 31 is a cross-sectional view illustrating a cross-section along I-II and a cross-section along III-IV in FIG. 30. The anode of the first on-side diode D1_{ON} and the cathode of the first off-side diode D1_{OFF} are connected to the gate electrode 10. The first off-side diode D1_{OFF} and the first on-side diode DION are connected in reverse parallel. The cathode of the first on-side diode D1_{ON} is connected to the upper electrode 14 via the gate wiring 18a and the contact 20a. The anode of the first off-side diode D1_{OFF} is connected to the upper electrode 14 via the gate wiring 18b and the contact 20b. The first on-side diode D1_{ON} and the first on-resistor R1_{ON} are connected in series. The first off-side diode D1_{OFF} and the first off-resistor R1_{OFF} are connected in series. The first resistor R1 corresponds to the sum of the first on-resistor R1_{ON} and the resistance of the gate wiring 18a when turn-on, and to the sum of the first off-resistor R1_{OFF} and the resistance of the gate wiring 18b when turn-off.

The anode of the second on-side diode D2_{ON} and the cathode of the second off-side diode D2_{OFF} are connected to the gate electrode 10. The second off-side diode D2_{OFF} and the second on-side diode D2_{ON} are connected in reverse parallel. The cathode of the second on-side diode D2_{ON} is connected to the lower electrode 12 via the gate wiring 19a and the contact 21a. The anode of the second off-side diode D2_{OFF} is connected to the lower electrode 12 via the gate wiring 19b and the contact 21b. The second on-side diode D2_{ON} and the second on-resistor R2_{ON} are connected in series. The second off-side diode D2_{OFF} and the second off-resistor R2_{OFF} are connected in series. The second resistor R2 corresponds to the sum of the second on-resistor R2_{ON} and the resistance of the gate wiring 19a when turned on, and to the sum of the second off-resistor R2_{OFF} and the resistance of the gate wiring 19b when turned off. Other configurations are the same as in the first embodiment.

Since the on and off signals of the gate signal flow through the first resistor R1 and the second resistor R2 in common, the turn-on and turn-off speeds cannot be optimized individually. Therefore, a first turn-on resistor R1_{ON} and a first turn-off resistor R1_{OFF} are respectively connected in series with a first on-side diode D1_{ON} and a first off-side diode D1_{OFF} which are connected in reverse parallel. A second on-resistor R2_{ON} and a second off-resistor R2_{OFF} are respectively connected in series to a second on-side diode D2_{ON} and a second off-side diode D2_{OFF}, which are connected in inverse parallel. This allows for changing the gate current during turn-on and turn-off periods respectively. This allows for optimal control with low switching losses while reducing electromagnetic noise both upon turn-on and upon turn-off.

In IGBTs, which are bipolar devices, the switching speed during the on-state is generally faster than during the off-state, which is influenced by holes, and this often leads to noise, making it more prone to constraints on switching speed. To increase the speed on the off-side, which is less constrained by switching speed, it is preferable to make the first off-resistor R1_{OFF} smaller than the first on-resistor R1_{ON}, and make the second off-resistor R2_{OFF} smaller than the second on-resistor R2_{ON}. Further, by performing structural design that reduces the hole density within the device, such as reducing the concentration of the collector layer 5 or decreasing the carrier lifetime, there can also be cases where the off-side speed becomes faster than the on-side speed. In that case, make the first off-resistor R1_{OFF} larger than the first on-resistor R1_{ON}, and make the second on-resistor R2_{ON} larger than the second on-resistor R2_{ON}.

### Fifteenth Embodiment

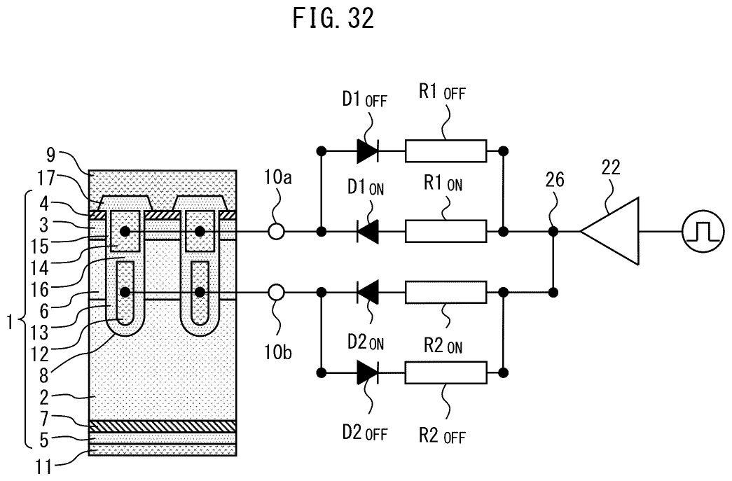

FIG. 32 is a top view illustrating a semiconductor device according to a fifteenth embodiment. The cathode of the first on-side diode DION and the anode of the first off-side diode D1_{OFF} are connected to the upper electrode 14 via the first gate electrode 10a. The anode of the first on-side diode DION and the cathode of the first off-side diode D1_{OFF} are connected to the input terminal 26. The first off-side diode D1_{OFF} and the first on-side diode D1_{ON} are connected in inverse parallel. The first on-side diode DION and the first on-resistor R1_{ON} are connected in series. The first off-side diode D1_{OFF} and the first off-resistor R1_{OFF} are connected in series. The first resistor R1 corresponds to the first on-resistor R1_{ON} when turned on, and to the first off-resistor R1_{OFF} when turned off.

The cathode of the second on-side diode D2_{ON} and the anode of the second off-side diode D2_{OFF} are connected to the upper electrode 14 via the second gate electrode 10b. The anode of the second on-side diode D2_{ON} and the cathode of the second off-side diode D2_{OFF} are connected to the input terminal 26. The second off-side diode D2_{OFF} and the second on-side diode D2_{ON} are connected in reverse parallel. The second on-side diode D2_{ON} is connected in series with the second on-resistor R2_{ON}. The second off-side diode D2_{OFF} is connected in series with the second off-resistor R2_{OFF}. The other configurations are the same as the eighth embodiment.

Since the on signal and the off signal of the gate signal flow through the first resistor R1 and the second resistor R2 in common, the turn-on speed and the turn-off speed cannot be optimized respectively. Therefore, the first on resistor RION and the first off resistor R1_{OFF} are connected in series to the first on-side diode D1_{ON} and the first off-side diode D1_{OFF}, which are connected in reverse parallel. A second on-resistor R2_{ON} and a second off-resistor R2_{OFF} are connected in series to a second on-side diode D2_{ON} and a second off-side diode D2_{OFF}, which are connected in inverse parallel. This allows the gate current to be changed for each of upon turn-on and turn-off. This allows for optimal control with low switching losses while reducing electromagnetic noise upon both turn-on and turn-off.

### Sixteenth Embodiment

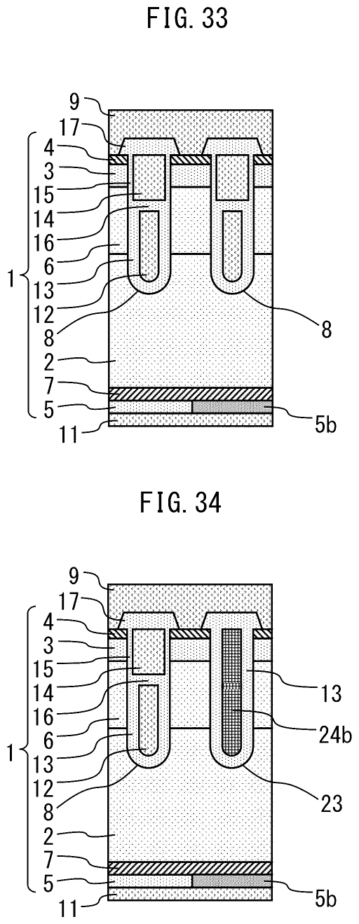

FIG. 33 is a cross-sectional view illustrating a semiconductor device according to a sixteenth embodiment. The semiconductor device according to the present embodiment is a Reverse Conducting IGBT (RC-IGBT) comprising an IGBT region including a collector layer 5 of a second conductive type, and a diode region including a cathode layer 5b of a first conductive type formed below the drift layer 2. In an RC-IGBT, during recovery operation, holes that were flowing in the diode region can flow into the IGBT region, generating a displacement current, increasing Icp, and potentially worsening noise. By applying the configuration of the present disclosure, it is possible to suppress noise even in an RC-IGBT. FIG. 34 is a cross-sectional view illustrating a modification of the semiconductor device according to the sixteenth embodiment. In the diode region, a dummy trench 23 is placed instead of the trench 8. This allows for a reduction in gate capacitance.

In the above first to sixteenth embodiments, the first resistor R1 and the second resistor R2 may serve as means for creating a difference in the magnitude of the gate current, in other words, means for creating a difference in the speed (mobility) at which charge flows. For example, the first resistor R1 and the second resistor R2 may be ICs in the gate drive circuit or may be the on-resistance of MOSFETs in the gate drive circuit.

When the semiconductor devices mentioned above are connected in parallel, differences may occur in gate wiring lengths, etc., due to chip arrangement, resulting in uneven wiring inductance, causing imbalances in current distribution during switching, and making noise more likely to occur. By applying the above embodiments, it is possible to reduce noise even when multiple semiconductor devices are connected in parallel.

It is preferable to integrate the semiconductor substrate 1 with the input terminal 26 on outside of the substrate, the first resistor R1, the second resistor R2, the gate drive circuit 22, etc., onto the circuit board. This allows the semiconductor device to be miniaturized. Further, through the reduction of the number of components and the simplification of the design, the parasitic inductance component that influences electromagnetic noise can be reduced, thus it is possible to reduce electromagnetic noise.

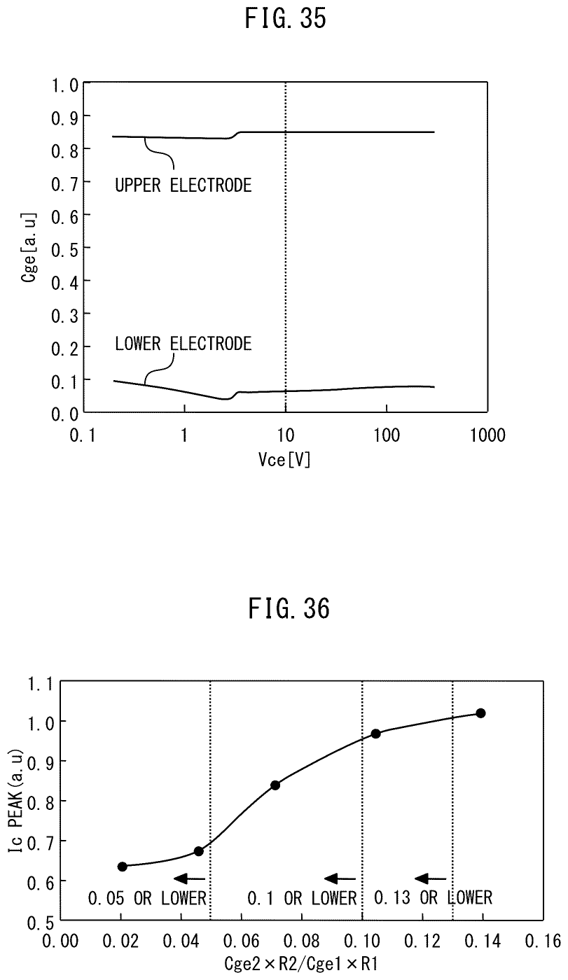

FIG. 35 is a view indicating Vce dependence of Cge. Vge=0V. The gate capacitance changes with Vce, but in the present disclosure, Cge is the gate-emitter capacitance under the conditions of Vce=10V and Vge=0V, as generally used in IGBT product datasheets. The same applies to Cies and Cgc.

FIG. 36 is a view indicating a relationship between the IC peak and the ratio of a CR time constant that is a product of gate-emitter capacitance of the upper electrode and the second resistance with respect to a CR time constant that is a product of gate-emitter capacitance of the upper electrode and the first resistance. The smaller the ratio of a CR time constant (Cge2×R2) that is the product of gate-emitter capacitance Cge2 of the lower electrode 12 and the second resistor R2 with respect to a CR time constant (Cge1×R1) that is the product of gate-emitter capacitance Cge1 of the upper electrode 14 and the first resistor R1, the lower the Ic peak. The Ic peak is reduced by decreasing the ratio, decreases slowly when the ratio is 0.13 to 0.1, decreases steeply when the ratio is 0.1 to 0.05, and decreases further even if the ratio is less than 0.05. By reducing the ratio to 0.13 or less, the capacitance of the lower electrode 12 can be charged faster, thereby reducing electromagnetic noise. It is preferable to set the ratio to 0.1 or less, and it is even more preferable to set it to 0.05 or less. The same applies to the relationship between Cge2×R2′/Cge1×R1′ and Ic peak.

The upper limit of the resistance values for the first resistor R1 and the second resistor R2 is, for example, 10,0000Ω or less, preferably 1,000Ω or less, and even more preferably 1000Ω or less. This allows for shortening the charging periods of the upper electrode 14 and the lower electrode 12, enabling the reduction of switching losses and noise. Further, the lower limit of the resistance values for the first resistor R1 and the second resistor R2 is, for example, 0Ω or more, preferably 1Ω or more, and even more preferably 10Ω or more. This allows the amount of gate current flowing to each of the upper 14 and lower 12 electrodes to be adjusted, thereby reducing switching losses and noise.

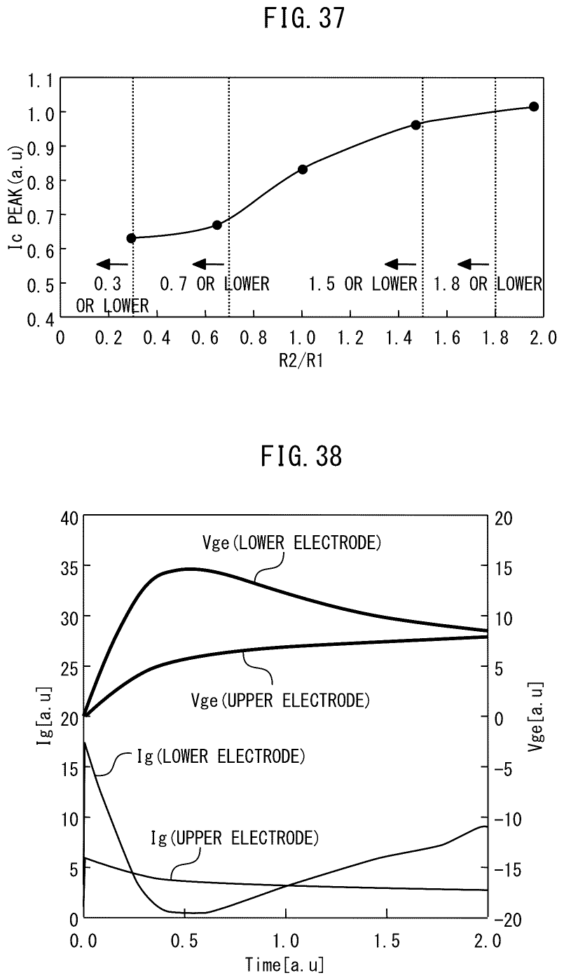

FIG. 37 is a view indicating a relationship between the IC peak and the ratio of the resistance of the second resistor with respect to the resistance of the first resistor. By setting the resistance ratio at 1.8 or less, the capacitance of the lower electrode 12 can be charged faster, thereby reducing electromagnetic noise. The IC peak reduces when the ratio decreases: it decreases gradually when the ratio is from 1.8 to 1.5, decreases sharply when the ratio is from 1.5 to 0.7, and continues to decrease even when the ratio is below 0.3. Therefore, lowering the ratio to 1.5 or less can further reduce electromagnetic noise. It is preferable to keep the ratio below 0.7, and even more preferable to keep it below 0.3. Further, to reduce the ratio, the resistance value of the second resistor R2 may be set to 1Ω or less, or even to 0Ω. When the resistance value of the second resistor R2 is 0Ω, the value of the gate current is controlled by the resistance of the second gate wiring 19 or the wiring resistance of the lower electrode 12 itself. Further, the relationship between the ratio of a resistance value of resistor R2′ to a resistance value of resistor R1′ and the IC peak is also similar.

FIG. 38 is a view indicating current and voltage of the lower and upper electrodes upon turn-on. In the gate voltage increase initial period upon turn-on, there is a period where the current in the lower electrode 12 is higher than the current in the upper electrode 14. This allows the lower electrode 12 to charge faster and reduces electromagnetic noise.

The semiconductor substrate 1 is not limited to a substrate formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved.

### Seventeenth Embodiment

In the present embodiment, the semiconductor devices according to the first to sixteenth embodiments described above are applied to an electric power conversion device, and the power conversion system including this power conversion device is configured. Although the present disclosure is not limited to a specific electric power conversion device, a case where the present disclosure is applied to a three-phase inverter will be described below.

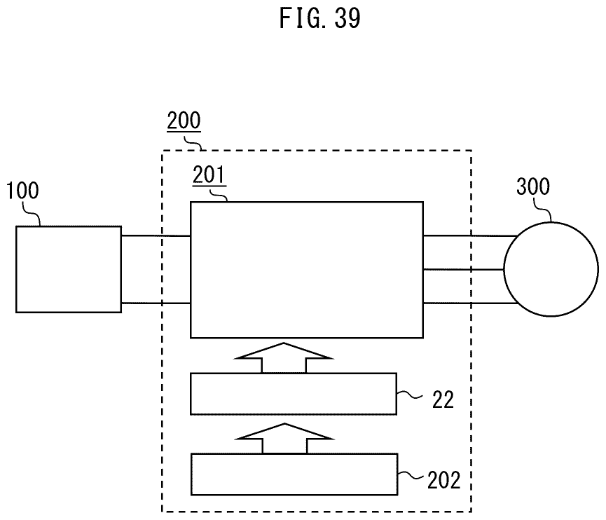

FIG. 39 is a block diagram illustrating a configuration of an electric power conversion system to which the electric power conversion device according to the seventeenth embodiment is applied. This electric power conversion system includes a power supply 100, an electric power conversion device 200, and a load 300. The power supply 100 is a DC power supply and supplies DC power to the electric power conversion device 200. The power supply 100 can be composed of various components. For example, the power supply 100 can be composed of a DC system, a solar cell, or a storage battery, or may be composed of a rectifier or an AC/DC converter, which is connected to an AC system. Alternatively, the power supply 100 may be composed of a DC/DC converter that convers DC power output from a DC system to predetermined power.

The electric power conversion device 200 is a three-phase inverter connected to a node between the power supply 100 and the load 300, converts DC power supplied from the power supply 100 into AC power, and supplies the AC power to the load 300. The electric power conversion device 200 includes a main conversion circuit 201 that converts DC power into AC power and outputs the AC power, a gate drive circuit 22 that outputs drive signals for driving each switching device of the main conversion circuit 201, and a control circuit 202 that outputs a control signal for controlling the gate drive circuit 22 to the gate drive circuit 22.

The load 300 is a three-phase electric motor that is driven by AC power supplied from the electric power conversion device 200. The load 300 is not limited to a specific application. The load is used as an electric motor mounted on various electric devices, such as an electric motor for, for example, a hybrid vehicle, an electric vehicle, a railroad vehicle, an elevator, or an air-conditioner.

The electric power conversion device 200 will be described in detail below. The main conversion circuit 201 includes a switching device and a reflux diode (not illustrated). When the switching device is switched, the main conversion circuit 201 converts DC power supplied from the power supply 100 into AC power, and supplies the AC power to the load 300. The main conversion circuit 201 may have various types of specific circuit configurations. The main conversion circuit 201 according to the present embodiment is a two-level three-phase full-bridge circuit, which can be composed of six switching devices and six reflux diodes connected in antiparallel with the respective switching devices. Each switching device of the main conversion circuit 201 is composed of a semiconductor device corresponding to any one of the first to sixteenth embodiments described above. Every two switching devices of the six switching devices are connected in series and constitute a vertical arm. Each vertical arm constitutes each phase (U-phase, V-phase, W-phase) of the full-bridge circuit. Output terminals of each vertical arm, i.e., three output terminals of the main conversion circuit 201, are connected to the load 300.

To increase the current that the power conversion device 200 can handle, the main conversion circuit 201 has a plurality of switching devices, in other words, a plurality of semiconductor devices, which can be connected in parallel in the main conversion circuit 201.

Here, if the semiconductor devices according to the first to sixteenth embodiments described above are used for the plurality of switching devices, preferably all switching devices, the noise generated from the power conversion device can be reduced. RC (Reverse Conducting)-IGBTs, which play the role of reflux diodes, can also be used as switching devices.

The gate drive circuit 22 generates a drive signal for driving each switching device of the main conversion circuit 201, and supplies the generated drive signal to a control electrode of each switching device of the main conversion circuit 201. Specifically, the drive circuit outputs, to the control electrode of each switching device, a drive signal for turning on each switching device and a drive signal for turning off each switching device, according to the control signal output from the control circuit 202, which is described later. When the ON-state of each switching device is maintained, the drive signal is a voltage signal (ON signal) having a voltage equal to or higher than a threshold voltage of the switching device. When the OFF-state of each switching device is maintained, the drive signal is a voltage signal (OFF signal) having a voltage equal to or lower than the threshold voltage of the switching device.

The control circuit 202 controls each switching device of the main conversion circuit 201 so as to supply a desired power to the load 300. Specifically, the control circuit 203 calculates a period (ON period), in which each switching device of the main conversion circuit 201 is in the ON state, based on the power to be supplied to the load 300. For example, the main conversion circuit 201 can be controlled by a PWM control for modulating the ON period of each switching device depending on the voltage to be output. Further, the control circuit 202 outputs a control command (control signal) to the gate drive circuit 22 so that the ON signal is output to each switching device to be turned on and an OFF signal is output to each switching device to be turned off at each point.

The gate drive circuit 22 outputs the ON signal or OFF signal, as the drive signal, to the control electrode of each switching device according to the control signal.

In the power conversion device 200 according to the present embodiment, the semiconductor devices according to the first to sixteenth embodiments are applied as the switching devices of the main conversion circuit 201, so that the power conversion device 200 with low loss and high speed switching reliability can be realized.

While the present embodiment illustrates an example in which the present disclosure is applied to a two-level three-phase inverter, the present disclosure is not limited to this and can be applied to various electric power conversion devices 200. While the present embodiment illustrates a two-level electric power conversion device 200, the present disclosure can also be applied to a three-level or multi-level electric power conversion device 200. When power is supplied to a single-phase load, the present disclosure may be applied to a single-phase inverter. The present disclosure can also be applied to a DC/DC converter or an AC/DC converter when power is supplied to a DC load or the like.

Further, in the electric power conversion device 200 to which the present disclosure is applied, the above-mentioned load 300 is not limited to an electric motor. For example, the load may also be used as a power supply device for an electric discharge machine, a laser beam machine, an induction heating cooker, or a non-contact device power feeding system. More alternatively, the electric power conversion device may be used as a power conditioner for a photovoltaic power generating system, an electricity storage system, or the like.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A semiconductor device comprising:
a semiconductor substrate including a drift layer of a first conductive type, a base layer of a second conductive type formed on the drift layer, a source layer of a first conductive type formed on the base layer, and a collector layer of a second conductive type formed below the drift layer;
an emitter electrode formed on an upper surface of the semiconductor substrate and connected to the base layer and the source layer;
a collector electrode formed on a lower surface of the semiconductor substrate and connected to the collector layer;
a lower electrode formed inside a trench penetrating the source layer and the base layer from the upper surface of the semiconductor substrate via a lower gate insulating film;
an upper electrode formed inside the trench via an upper gate insulating film, positioned above the lower electrode and separated from the lower electrode by an intermediate insulating film;
an input terminal;
a first resistor connected between the upper electrode and the input terminal; and
a second resistor connected between the lower electrode and the input terminal, wherein gate-emitter capacitance of the lower electrode is smaller than gate-emitter capacitance of the upper electrode.

### (Supplementary Note 2)

The semiconductor device according to Supplementary Note 1, wherein the input terminal is a gate electrode formed on the upper surface of the semiconductor substrate.

### (Supplementary Note 3)

The semiconductor device according to Supplementary Note 1, wherein the input terminal, the first resistor and the second resistor are formed outside the semiconductor substrate.

### (Supplementary Note 4)

The semiconductor device according to any one of Supplementary Notes 1 to 3, wherein there is a period during which a voltage of the lower electrode is higher than a voltage of the upper electrode during a current increase period upon turn-on.

### (Supplementary Note 5)

The semiconductor device according to any one of Supplementary Notes 1 to 4, wherein a gate voltage increase initial period upon turn-on includes a period where a current in the lower electrode is higher than a current in the upper electrode.

### (Supplementary Note 6)

The semiconductor device according to any one of Supplementary Notes 1 to 5, wherein a ratio of gate-emitter capacitance of the lower electrode with respect to gate-emitter capacitance of the upper electrode is equal to or less than 0.5.

### (Supplementary Note 7)

The semiconductor device according to any one of Supplementary Notes 1 to 5, wherein a ratio of gate-emitter capacitance of the lower electrode with respect to gate-emitter capacitance of the upper electrode is equal to or less than 0.2.

### (Supplementary Note 8)

The semiconductor device according to any one of Supplementary Notes 1 to 7, wherein there is a period during which a voltage of the lower electrode is lower than a voltage of the upper electrode during a miller period upon turn-on.

### (Supplementary Note 9)

The semiconductor device according to any one of Supplementary Notes 1 to 8, wherein a thickness of the lower gate insulating film that covers a side surface and a bottom portion of the lower electrode is thicker than a thickness of the upper gate insulating film that covers a side surface of the upper electrode.

### (Supplementary Note 10)

The semiconductor device according to Supplementary Note 9, wherein a thickness of the lower gate insulating film is equal to or greater than 1.5 times of a thickness of the upper gate insulating film.

### (Supplementary Note 11)

The semiconductor device according to Supplementary Note 9, wherein a thickness of the lower gate insulating film is equal to or greater than 2 times of a thickness of the upper gate insulating film.

### (Supplementary Note 12)

The semiconductor device according to Supplementary Note 9, wherein a thickness of the lower gate insulating film is equal to or greater than 2.5 times of a thickness of the upper gate insulating film.

### (Supplementary Note 13)

The semiconductor device according to any one of Supplementary Notes 1 to 12, wherein a thickness of the intermediate insulating film is thicker than a thickness of the upper gate insulating film on a side surface of the upper electrode.

### (Supplementary Note 14)

The semiconductor device according to any one of Supplementary Notes 1 to 13, wherein a CR time constant comprised of gate capacitance of the lower electrode and the second resistor is smaller than a CR time constant comprised of gate capacitance of the upper electrode and the first resistor.

### (Supplementary Note 15)

The semiconductor device according to any one of Supplementary Notes 1 to 14, wherein a ratio of a CR time constant that is a product of gate-emitter capacitance of the lower electrode and the second resistor with respect to a CR time constant that is a product of gate-emitter capacitance of the upper electrode and the first resistor is 0.13 or less.

### (Supplementary Note 16)

The semiconductor device according to any one of Supplementary Notes 1 to 15, wherein a resistance value of the second resistor is smaller than a resistance value of the first resistor.

### (Supplementary Note 17)

The semiconductor device according to any one of Supplementary Notes 1 to 15, wherein a resistance value of the second resistor is larger than a resistance value of the first resistor.

### (Supplementary Note 18)

The semiconductor device according to any one of Supplementary Notes 1 to 15, wherein a ratio of resistance of the second resistor with respect to resistance of the first resistor is 1.8 or less.

### (Supplementary Note 19)

The semiconductor device according to any one of Supplementary Notes 1 to 18, further comprising a carrier accumulation layer of a first conductive type formed between the drift layer and the base layer and having higher impurity concentration than that of the drift layer.

### (Supplementary Note 20)

The semiconductor device according to Supplementary Note 19, wherein a length of the carrier accumulation layer facing a side surface of the lower electrode is longer than a length of the carrier accumulation layer facing a side surface of the upper electrode.

### (Supplementary Note 21)

The semiconductor device according to Supplementary Note 19, wherein a length of the carrier accumulation layer facing a side surface of the lower electrode is longer than a length of the drift layer facing a side surface of the lower electrode.

### (Supplementary Note 22)

The semiconductor device according to any one of Supplementary Notes 1 to 21, wherein a length of the lower electrode is longer than a length of the upper electrode extending below the base layer.

### (Supplementary Note 23)

The semiconductor device according to any one of Supplementary Notes 1 to 22, wherein a depth of the base layer is longer than a length of the upper electrode extending below the base layer.

### (Supplementary Note 24)

The semiconductor device according to any one of Supplementary Notes 1 to 23, wherein a plurality of the trenches are formed on the semiconductor substrate side-by-side, and a mesa width between the adjacent trenches is narrower than a width of the trench.

### (Supplementary Note 25)

The semiconductor device according to Supplementary Note 2, further comprising a first gate wiring connecting the upper electrode and the gate electrode, and a second gate wiring connecting the lower electrode and the gate electrode,
wherein a length of the second gate wiring is shorter than a length of the first gate wiring.

### (Supplementary Note 26)

The semiconductor device according to Supplementary Note 2, further comprising a first gate wiring connecting the upper electrode and the gate electrode, and a second gate wiring connecting the lower electrode and the gate electrode,
wherein a length of the second gate wiring is longer than a length of the first gate wiring.

### (Supplementary Note 27)

The semiconductor device according to Supplementary Note 25, wherein the upper electrode is connected to the first gate wiring via a first gate contact, and
the lower electrode is connected to the second gate wiring via a second gate contact.

### (Supplementary Note 28)

The semiconductor device according to Supplementary Note 2, further comprising a gate resistor formed outside the semiconductor substrate and connected to the gate electrode,
wherein the gate resistor has a resistance value greater than resistance values of the first resistor and the second resistor and is formed outside the semiconductor substrate.

### (Supplementary Note 29)

The semiconductor device according to Supplementary Note 2, further comprising a gate resistor formed outside the semiconductor substrate and connected to the gate electrode,
wherein the gate resistor has a smaller resistance value than the first resistor and the second resistor, and is formed outside the semiconductor substrate.

### (Supplementary Note 30)

The semiconductor device according to any one of Supplementary Notes 1 to 29, further comprising a dummy lower electrode formed inside a dummy trench penetrating the source layer and the base layer from the upper surface of the semiconductor substrate via the lower gate insulating film and connected to the emitter electrode,
wherein the upper electrode is formed inside the dummy trench via the upper gate insulating film, positioned above the dummy lower electrode, and separated from the dummy lower electrode by the intermediate insulating film.

### (Supplementary Note 31)

The semiconductor device according to any one of Supplementary Notes 1 to 29, further comprising a dummy upper electrode formed inside a dummy trench penetrating the source layer and the base layer from the upper surface of the semiconductor substrate via the upper gate insulating film and connected to the emitter electrode,
wherein the lower electrode is formed inside the dummy trench via the lower gate insulating film, positioned below the dummy upper electrode, and separated from the dummy upper electrode via the intermediate insulating film.

### (Supplementary Note 32)

The semiconductor device according to any one of Supplementary Notes 1 to 29, further comprising a dummy lower electrode formed inside a dummy trench penetrating the source layer and the base layer from the upper surface of the semiconductor substrate via the lower gate insulating film and connected to the emitter electrode, and
a dummy upper electrode formed inside the dummy trench via the upper gate insulating film, positioned above the dummy lower electrode and separated from the dummy lower electrode by the intermediate insulating film.

### (Supplementary Note 33)

The semiconductor device according to any one of Supplementary Notes 1 to 29, further comprising a dummy electrode formed inside a dummy trench penetrating the source layer and the base layer from the upper surface of the semiconductor substrate via a gate insulating film and connected to the emitter electrode.

### (Supplementary Note 34)

The semiconductor device according to any one of Supplementary Notes 1 to 33, comprising at least one of a first capacitor connected between the upper electrode and an emitter, and a second capacitor connected between the lower electrode and the emitter.

### (Supplementary Note 35)

The semiconductor device according to Supplementary Note 34, wherein a sum of a gate-emitter capacitance of the lower electrode and the second capacitor is smaller than a sum of a gate-emitter capacitance of the upper electrode and the first capacitor.

### (Supplementary Note 36)

The semiconductor device according to any one of Supplementary Notes 1 to 33, comprising at least one of a first capacitor connected between the upper electrode and a collector, and a second capacitor connected between the lower electrode and the collector.

### (Supplementary Note 37)

The semiconductor device according to any one of Supplementary Notes 1 to 36, comprising a first diode having a cathode connected to the upper electrode and an anode connected to ground or an emitter, or a second diode having a cathode connected to the lower electrode and an anode connected to ground or emitter.

### (Supplementary Note 38)

The semiconductor device according to any one of Supplementary Notes 1 to 36, comprising a clamp circuit connected to the upper electrode or the lower electrode.

### (Supplementary Note 39)

The semiconductor device according to any one of Supplementary Notes 1 to 38, further comprising
an on-side diode having a cathode connected to the input terminal,
an off-side diode having an anode connected to the input terminal and connected in reverse-parallel to the on-side diode,
an on-resistor connected in series to the on-side diode, and
an off-resistor connected in series to the off-side diode.

### (Supplementary Note 40)

The semiconductor device according to any one of Supplementary Notes 1 to 39, comprising
a first on-side diode having an anode connected to the input terminal and a cathode connected to the upper electrode,
a first on-resistor connected in series to the first on-side diode,
a first off-side diode having a cathode connected to the input terminal and an anode connected to the upper electrode, and connected in reverse parallel to the first on-side diode,
a first off-resistor connected in series to the first off-side diode,
a second on-side diode having an anode connected to the input terminal and a cathode connected to the lower electrode,
a second on-resistor connected in series to the second on-side diode,
a second off-side diode having a cathode connected to the input terminal and an anode connected to the lower electrode, and connected in reverse parallel to the second on-side diode, and
a second off-resistor connected in series to the second off-side diode,
wherein the first resistor includes the first on-resistor or the first off-resistor, and
the second resistor includes the second on-resistor or the second off-resistor.

### (Supplementary Note 41)

The semiconductor device according to Supplementary Note 40, wherein the first off-resistor is smaller than the first on-resistor, and
the second off-resistor is smaller than the second on-resistor.

### (Supplementary Note 42)

The semiconductor device according to any one of Supplementary Notes 1 to 41, comprising an IGBT region including the collector layer, and a diode region including a cathode layer of a first conductive type formed below the drift layer.

### (Supplementary Note 43)

The semiconductor device wherein the semiconductor devices according to any one of Supplementary Notes 1 to 42 are connected in parallel.

### (Supplementary Note 44)

The semiconductor device according to any one of Supplementary Notes 1 to 43, wherein the semiconductor substrate, the input terminal, the first resistor and the second resistor are integrated.

### (Supplementary Note 45)

The semiconductor device according to any one of Supplementary Notes 1 to 44, wherein the semiconductor substrate is formed of a wide-bandgap semiconductor.

### (Supplementary Note 46)

The semiconductor device according to any one of Supplementary Notes 1 to 45, further comprising a gate drive circuit supplying a gate signal to the input terminal.

### (Supplementary Note 47)

An electric power conversion device comprising:
a main conversion circuit including the semiconductor device according to any one of Supplementary Notes 1 to 46, converting input power and outputting converted power;
a drive circuit outputting a drive signal for driving the semiconductor device to the semiconductor device, and
a control circuit outputting a control signal for controlling the drive circuit to the drive circuit.

### REFERENCE SIGNS LIST

1 semiconductor substrate; 2 drift layer; 3 base layer; 4 source layer; 5 collector layer; 6 carrier accumulation layer; 8 trench; 9 emitter electrode; 10 gate electrode (input terminal); 11 collector electrode; 12 lower electrode; 13 lower gate insulating film; 14 upper electrode; 15 upper gate insulating film; 16 intermediate insulating film; 18 first gate wiring; 19 second gate wiring; 20 first gate contact; 21 second gate contact; 22 gate drive circuit; 23 dummy trench; 24 dummy lower electrode; 25 dummy upper electrode; 26 input terminal; C1 first capacitor; C2 second capacitor; D1,D1′ first diode (clamp circuit); D2,D2′ second diode (clamp circuit); D_{ON} on-side diode; D_{OFF} off-side diode; D1_{ON} first on-side diode; D1_{OFF} first off-side diode; D2_{ON} second on-side diode; D2_{OFF} second off-side diode; R1 first resistor; R2 second resistor; R3 gate resistor; R_{ON} on-resistor; R_{OFF} off-resistor; R1_{ON} first on-resistor; R1_{OFF} first off-resistor; R2_{ON} second on-resistor; R2_{OFF} second off-resistor; 200 electric power conversion device; 201 main conversion circuit; 202 control circuit

Obviously many modifications and variations of the present disclosure are possible in the light of the above teachings. It is therefore to be understood that within the scope of the appended claims the invention may be practiced otherwise than as specifically described.

The entire disclosures of Japanese Patent Application No. 2024-080264, filed on May 16, 2024 and Japanese Patent Application No. 2025-61318, filed on Apr. 2, 2025 including specification, claims, drawings and summary, on which the convention priority of the present application is based, is incorporated herein by reference in its entirety.

1. A semiconductor device comprising:
a semiconductor substrate including a drift layer of a first conductive type, a base layer of a second conductive type formed on the drift layer, a source layer of a first conductive type formed on the base layer, and a collector layer of a second conductive type formed below the drift layer;
an emitter electrode formed on an upper surface of the semiconductor substrate and connected to the base layer and the source layer;
a collector electrode formed on a lower surface of the semiconductor substrate and connected to the collector layer;
a lower electrode formed inside a trench penetrating the source layer and the base layer from the upper surface of the semiconductor substrate via a lower gate insulating film;
an upper electrode formed inside the trench via an upper gate insulating film, positioned above the lower electrode and separated from the lower electrode by an intermediate insulating film;
an input terminal;
a first resistor connected between the upper electrode and the input terminal; and
a second resistor connected between the lower electrode and the input terminal,
wherein gate-emitter capacitance of the lower electrode is smaller than gate-emitter capacitance of the upper electrode.

2. The semiconductor device according to claim 1, wherein the input terminal is a gate electrode formed on the upper surface of the semiconductor substrate.

3. The semiconductor device according to claim 1, wherein the input terminal, the first resistor and the second resistor are formed outside the semiconductor substrate.

4. The semiconductor device according to claim 1, wherein there is a period during which a voltage of the lower electrode is higher than a voltage of the upper electrode during a current increase period upon turn-on.

5. The semiconductor device according to claim 1, wherein a gate voltage increase initial period upon turn-on includes a period where a current in the lower electrode is higher than a current in the upper electrode.

6. The semiconductor device according to claim 1, wherein a ratio of gate-emitter capacitance of the lower electrode with respect to gate-emitter capacitance of the upper electrode is equal to or less than 0.5.

7. The semiconductor device according to claim 1, wherein a ratio of gate-emitter capacitance of the lower electrode with respect to gate-emitter capacitance of the upper electrode is equal to or less than 0.2.

8. The semiconductor device according to claim 1, wherein there is a period during which a voltage of the lower electrode is lower than a voltage of the upper electrode during a miller period upon turn-on.

9. The semiconductor device according to claim 1, wherein a thickness of the lower gate insulating film that covers a side surface and a bottom portion of the lower electrode is thicker than a thickness of the upper gate insulating film that covers a side surface of the upper electrode.

10. The semiconductor device according to claim 9, wherein a thickness of the lower gate insulating film is equal to or greater than 1.5 times of a thickness of the upper gate insulating film.

11. The semiconductor device according to claim 9, wherein a thickness of the lower gate insulating film is equal to or greater than 2 times of a thickness of the upper gate insulating film.

12. The semiconductor device according to claim 9, wherein a thickness of the lower gate insulating film is equal to or greater than 2.5 times of a thickness of the upper gate insulating film.

13. The semiconductor device according to claim 1, wherein a thickness of the intermediate insulating film is thicker than a thickness of the upper gate insulating film on a side surface of the upper electrode.

14. The semiconductor device according to claim 1, wherein a CR time constant comprised of gate capacitance of the lower electrode and the second resistor is smaller than a CR time constant comprised of gate capacitance of the upper electrode and the first resistor.

15. The semiconductor device according to claim 1, wherein a ratio of a CR time constant that is a product of gate-emitter capacitance of the lower electrode and the second resistor with respect to a CR time constant that is a product of gate-emitter capacitance of the upper electrode and the first resistor is 0.13 or less.

16. The semiconductor device according to claim 1, wherein a resistance value of the second resistor is smaller than a resistance value of the first resistor.

17. The semiconductor device according to claim 1, wherein a resistance value of the second resistor is larger than a resistance value of the first resistor.

18. The semiconductor device according to claim 1, wherein a ratio of resistance of the second resistor with respect to resistance of the first resistor is 1.8 or less.

19. The semiconductor device according to claim 1, further comprising a carrier accumulation layer of a first conductive type formed between the drift layer and the base layer and having higher impurity concentration than that of the drift layer.

20. The semiconductor device according to claim 19, wherein a length of the carrier accumulation layer facing a side surface of the lower electrode is longer than a length of the carrier accumulation layer facing a side surface of the upper electrode.

21. The semiconductor device according to claim 19, wherein a length of the carrier accumulation layer facing a side surface of the lower electrode is longer than a length of the drift layer facing a side surface of the lower electrode.

22. The semiconductor device according to claim 1, wherein a length of the lower electrode is longer than a length of the upper electrode extending below the base layer.

23. The semiconductor device according to claim 1, wherein a depth of the base layer is longer than a length of the upper electrode extending below the base layer.

24. The semiconductor device according to claim 1, wherein a plurality of the trenches are formed on the semiconductor substrate side-by-side, and
a mesa width between the adjacent trenches is narrower than a width of the trench.

25. The semiconductor device according to claim 2, further comprising a first gate wiring connecting the upper electrode and the gate electrode, and a second gate wiring connecting the lower electrode and the gate electrode,
wherein a length of the second gate wiring is shorter than a length of the first gate wiring.

26. The semiconductor device according to claim 2, further comprising a first gate wiring connecting the upper electrode and the gate electrode, and a second gate wiring connecting the lower electrode and the gate electrode,
wherein a length of the second gate wiring is longer than a length of the first gate wiring.

27. The semiconductor device according to claim 25, wherein the upper electrode is connected to the first gate wiring via a first gate contact, and
the lower electrode is connected to the second gate wiring via a second gate contact.

28. The semiconductor device according to claim 2, further comprising a gate resistor formed outside the semiconductor substrate and connected to the gate electrode,
wherein the gate resistor has a resistance value greater than resistance values of the first resistor and the second resistor and is formed outside the semiconductor substrate.

29. The semiconductor device according to claim 2, further comprising a gate resistor formed outside the semiconductor substrate and connected to the gate electrode,
wherein the gate resistor has a smaller resistance value than the first resistor and the second resistor, and is formed outside the semiconductor substrate.

30. The semiconductor device according to claim 1, further comprising a dummy lower electrode formed inside a dummy trench penetrating the source layer and the base layer from the upper surface of the semiconductor substrate via the lower gate insulating film and connected to the emitter electrode,
wherein the upper electrode is formed inside the dummy trench via the upper gate insulating film, positioned above the dummy lower electrode, and separated from the dummy lower electrode by the intermediate insulating film.

31. The semiconductor device according to claim 1, further comprising a dummy upper electrode formed inside a dummy trench penetrating the source layer and the base layer from the upper surface of the semiconductor substrate via the upper gate insulating film and connected to the emitter electrode,
wherein the lower electrode is formed inside the dummy trench via the lower gate insulating film, positioned below the dummy upper electrode, and separated from the dummy upper electrode via the intermediate insulating film.

32. The semiconductor device according to claim 1, further comprising a dummy lower electrode formed inside a dummy trench penetrating the source layer and the base layer from the upper surface of the semiconductor substrate via the lower gate insulating film and connected to the emitter electrode, and
a dummy upper electrode formed inside the dummy trench via the upper gate insulating film, positioned above the dummy lower electrode and separated from the dummy lower electrode by the intermediate insulating film.

33. The semiconductor device according to claim 1, further comprising a dummy electrode formed inside a dummy trench penetrating the source layer and the base layer from the upper surface of the semiconductor substrate via a gate insulating film and connected to the emitter electrode.

34. The semiconductor device according to claim 1, comprising at least one of a first capacitor connected between the upper electrode and an emitter, and a second capacitor connected between the lower electrode and the emitter.

35. The semiconductor device according to claim 34, wherein a sum of a gate-emitter capacitance of the lower electrode and the second capacitor is smaller than a sum of a gate-emitter capacitance of the upper electrode and the first capacitor.

36. The semiconductor device according to claim 1, comprising at least one of a first capacitor connected between the upper electrode and a collector, and a second capacitor connected between the lower electrode and the collector.

37. The semiconductor device according to claim 1, comprising a first diode having a cathode connected to the upper electrode and an anode connected to ground or an emitter, or a second diode having a cathode connected to the lower electrode and an anode connected to ground or emitter.

38. The semiconductor device according to claim 1, comprising a clamp circuit connected to the upper electrode or the lower electrode.

39. The semiconductor device according to claim 1, further comprising an on-side diode having a cathode connected to the input terminal,
an off-side diode having an anode connected to the input terminal and connected in reverse-parallel to the on-side diode,
an on-resistor connected in series to the on-side diode, and
an off-resistor connected in series to the off-side diode.

40. The semiconductor device according to claim 1, comprising
a first on-side diode having an anode connected to the input terminal and a cathode connected to the upper electrode,
a first on-resistor connected in series to the first on-side diode,
a first off-side diode having a cathode connected to the input terminal and an anode connected to the upper electrode, and connected in reverse parallel to the first on-side diode,
a first off-resistor connected in series to the first off-side diode,
a second on-side diode having an anode connected to the input terminal and a cathode connected to the lower electrode,
a second on-resistor connected in series to the second on-side diode,
a second off-side diode having a cathode connected to the input terminal and an anode connected to the lower electrode, and connected in reverse parallel to the second on-side diode, and
a second off-resistor connected in series to the second off-side diode,
wherein the first resistor includes the first on-resistor or the first off-resistor, and
the second resistor includes the second on-resistor or the second off-resistor.

41. The semiconductor device according to claim 40, wherein the first off-resistor is smaller than the first on-resistor, and
the second off-resistor is smaller than the second on-resistor.

42. The semiconductor device according to claim 1, comprising an IGBT region including the collector layer, and a diode region including a cathode layer of a first conductive type formed below the drift layer.

43. The semiconductor device wherein the semiconductor devices according to claim 1 are connected in parallel.

44. The semiconductor device according to claim 3, wherein the semiconductor substrate, the input terminal, the first resistor and the second resistor are integrated.

45. The semiconductor device according to claim 1, wherein the semiconductor substrate is formed of a wide-bandgap semiconductor.

46. The semiconductor device according to claim 1, further comprising a gate drive circuit supplying a gate signal to the input terminal.

47. An electric power conversion device comprising:
a main conversion circuit including the semiconductor device according to claim 1, converting input power and outputting converted power;
a drive circuit outputting a drive signal for driving the semiconductor device to the semiconductor device, and
a control circuit outputting a control signal for controlling the drive circuit to the drive circuit.
